(19) United States
(12) Patent Application Publication
(10) Pub. No.: US 2025/0280556 A1
(43) Pub. Date: Sep. 4, 2025

(54) METHOD FOR FORMING MOS TRANSISTOR STRUCTURE

(71) Applicant: Invention and Collaboration Laboratory, Inc., Taipei City (TW)

(72) Inventors: Chao-Chun LU, Hsinchu (TW); Li-Ping HUANG, Hsinchu (TW)

(73) Assignee: Invention and Collaboration Laboratory, Inc., Taipei City (TW)

(21) Appl. No.: 18/966,937

(22) Filed: Dec. 3, 2024

Related U.S. Application Data
(60) Provisional application No. 63/559,956, filed on Mar. 1, 2024.
(60) Provisional application No. 63/683,712, filed on Aug. 16, 2024.

(51) Int. Cl. H10D 30/01; H01L 21/762; H10D 30/62

(52) U.S. Cl. CPC H10D 30/024; H01L 21/76224; H10D 30/6215

(57) ABSTRACT

A method for forming a metal-oxide-semiconductor (MOS) transistor structure includes steps as follows: A plurality of fin structures is defined in a semiconductor substrate. A sacrificial spacer is formed surrounding sidewalls of each of the plurality of fin structures. A dielectric layer is formed to surround the sacrificial spacer. And after the sacrificial spacer is removed gate structures are respectively formed covering the sidewalls of each of the plurality of fin structures.

This application claims the benefit of U.S. provisional application Ser. No. 63/559,956 filed Mar. 1, 2024, and U.S. provisional Ser. No. 63/683,712, filed Aug. 16, 2024, and the subject matter of which is incorporated herein by reference.

### BACKGROUND OF THE DISCLOSURE

### Field of the Disclosure

The present invention relates to a method for forming an integrated circuit, and particularly to a method for forming a metal-oxide-semiconductor (MOS) transistor structure.

### Description of the Related Art

Monolithic integration of Silicon devices for integrated circuits (IC) has achieved realization of more than 50 billions of transistors on a die in the year of 2021, which has been named as an era of GSI (Gigabyte-Scale Integration, i.e. Achieving more than billions of transistors on a die) from VLSI (Very Large Scale Integration having more than millions of transistors on a die). Such accomplishments of making much higher integration capacity of transistors on a die have sharply enabled more powerful Microsystems with significantly improved PPAC (higher Performance, better Power Managing capability, effective usage of Area and lower Cost per bit), thus creating many powerful chips such as CPU, GPU, FPGA, SOC, SRAM, DRAM, etc., which enhances System capabilities so as to continually support Moore's Law which formed a base to create an exponential Economic growth.

With such a high productivity generated from GSI to grow new applications which stimulates fast growth of economic scale, there are very strong demands to integrate more transistors on a die. So it is expected that Semiconductor industry try every best effort to march toward a Tera-Scale Integration (TSI), that is, Integration of more than trillions of transistors on a die for a chip. Therefore, how to sharply improve the transistor to meet this TSI challenge requires Inventions and engineering improvements of for some fundamentally changed transistor structure with better PPAC. For example, if a chip does integrate one trillion transistors on a die, if each transistor is set at achieving a standby current (or called loff) about 0.5 pA (A is abbreviation of Ampere), then a total of one trillion of transistors will have its loff of a die is approaching 0.5 Amperes.

The state-of-art transistor with less than 20 nm technologies can hardly achieved this loff of 0.5 pA, however; even by using various transistor structures such as FinFET or Tri-Gate Designs, some loff can be as large as 5 to 10 pA. How to continuously shrink the device dimensions plus to reduce loff (such as lower than 1 pA) is the key challenge.

An example of state-of-the-art Field-Effect Transistor (FinFET) usually includes an active region which is formed as a Fin structure (as shown in FIG. 1). The transistor gate structure 5 using some conductive material (like metal, polysilicon or polycide, etc.) over an insulator or dielectric layer (such as oxide, oxide/nitride or some high-k dielectric, etc.) is formed over a fin-structure or a 3D silicon surface whose sidewalls are isolated from those of other transistors by using insulation materials (e.g. oxide or oxide/nitride or other dielectrics). Using an NMOS transistor as example, there are source region 11 and drain region 12 which are formed by an ion-implantation plus thermal annealing technique to implant high concentration n-type dopants into a p-type substrate (or a p-well) which thus results in two separated n+/p junction areas. Furthermore, to lessen impact ionization and hot carrier injection prior to highly doped n+/p junction, it is common to form a lightly doped-drain (LDD) region 13 before the highly doped n+ source/drain region 11/12 by Ion-implantation plus thermal annealing technique, and such ion-implantation plus thermal annealing technique frequently causes the LDD regions 13 penetrating into the portion of the 3D active regions which are underneath the gate structure 5. Therefore, the effective channel between the LDD regions 13 is unavoidably shortened.

On the other hand, the advancement of manufacturing process technologies is continuing to move forward rapidly by scaling down the geometries of devices in both horizontal and vertical dimensions (such as the minimum feature size called as Lamda (A) is shrunk from 28 nm down to 5 nm or 3 nm). But many problems are introduced or getting worse due to such FinFET or Trigate geometry scaling.

For example, as the device gate length is scaled down, the distance of the adjacent two fin structures cannot be well controlled by the conventional lithography and etch patterning technology. Furthermore, the gate electrode pitch or distance of two adjacent MOS transistors can be also hardly controlled as well by the conventional lithography and etch patterning technology.

In addition, as the device dimension is scaled down to 7 nm, 5 nm or 3 nm, the height of the Fin structure (such as 50-100 nm) is far larger than the width of the Fin structure (such as 3-10 nm) such that the fin structure is vulnerable or even collapsed during the subsequent processes (such as source/drain formation, gate formation, etc.).

### SUMMARY OF THE DISCLOSURE

One object of the present disclosure is to provide a method for forming a metal-oxide-semiconductor (MOS) transistor structure includes steps as follows: Firstly, a first fin structure and a second fin structure adjacent to the first fin structure are defined in a semiconductor substrate, wherein a shallow trench isolation (STI) region is between the first fin structure and the second fin structure. Next, a first sacrificial spacer is formed disposed along sidewalls of the first fin structure; and a second sacrificial spacer r is formed disposed along sidewalls of the second fin structure, wherein a gap is between the first sacrificial spacer and the second sacrificial space. Then, an inserting dielectric layer is formed to fill the gap between the first sacrificial spacer and the second sacrificial spacer. After removing the first sacrificial spacer and the second sacrificial spacer, two gate structures are formed over the first fin structure and the second fin structure respectively, wherein the two gate structures are separated by the inserting dielectric layer.

According to one embodiment of the present disclosure, the first sacrificial spacer and the second sacrificial spacer comprise an epitaxial semiconductor material selectively grown based on the sidewalls of the first fin structure and the second fin structure.

According to one embodiment of the present disclosure, prior to forming the first sacrificial spacer and the second sacrificial spacer, the method further includes steps as follows: firstly, a capping dielectric layer is formed covering the first fin structure and the second fin structure. And a gate opening is then defined in the capping dielectric layer to make the sidewalls of the first fin structure and the second fin structure partially exposed from the gate opening.

According to one embodiment of the present disclosure, the method further includes steps of forming a fin spacer to surround the sidewalls of the first fin structure and the second fin structure, prior to forming the capping dielectric layer; and performing at least one etching process to remove the fin spacer in the gate opening to make the sidewalls of the first fin structure and the second fin structure partially exposed, prior to forming the first sacrificial spacer and the second sacrificial spacer.

According to one embodiment of the present disclosure, the material constituting the inserting dielectric layer is different from that constituting the capping dielectric layer.

According to one embodiment of the present disclosure, the method further includes steps of deepening the gate opening to expose the semiconductor substrate, after the epitaxial semiconductor material is formed and prior to the gate opening is filled with the inserting dielectric layer.

According to one embodiment of the present disclosure, a portion of the semiconductor substrate is removed during the process of deepening the gate opening.

According to one embodiment of the present disclosure, a portion of the STI region is removed during deepening the gate opening, so as to remain another portion of the STI region beneath the epitaxial semiconductor material.

According to one embodiment of the present disclosure a bottom of the inserting dielectric layer is lower than a bottom of the another portion of the STI region.

According to one embodiment of the present disclosure, a dielectric constant of the inserting dielectric layer is lower than that of SiO₂.

According to one embodiment of the present disclosure, the first sacrificial spacer and the second sacrificial spacer comprises amorphous silicon covering the sidewalls of the first fin structure the second fin structure.

According to one embodiment of the present disclosure, the method further includes steps of forming a fin spacer to surround the sidewalls of the first fin structure and the second fin structure, prior to forming the first sacrificial spacer and the second sacrificial spacer.

According to one embodiment of the present disclosure, the method further includes steps of forming a capping dielectric layer covering the first fin structure, the second fin structure, the first sacrificial spacer, the second sacrificial spacer and the inserting dielectric layer; and defining a gate opening in the capping dielectric layer to make the sidewalls of the first fin structure and the second fin structure partially exposed from the gate opening.

According to one embodiment of the present disclosure, the method further includes steps of removing a portion of the STI region not covered by the first sacrificial spacer and the second sacrificial spacer to expose a portion of the semiconductor substrate, prior to removing the sacrificial spacer.

According to one embodiment of the present disclosure, a bottom of the inserting dielectric layer is lower than a bottom of another portion of the STI region beneath the first sacrificial spacer and the second sacrificial spacer.

Another object of the present disclosure is to provide a MOS transistor structure, wherein the MOS transistor structure includes a first active region, a second active region adjacent to the first active region, an inserting dielectric layer, a first trench, a second trench, a first gate structure and a second gate structure. The first active region and the second active region are formed in a semiconductor substrate, wherein a STI region is between the first active region and the second active region. The inserting dielectric layer is disposed between the first active region and the second active region. The first trench is surrounding or over the first active region, wherein the first trench is adjacent to one side of the inserting dielectric layer. The second trench is surrounding or over the second active region, wherein the second trench is adjacent to another side of the inserting dielectric layer. The first gate structure is over the first active region and within the first trench, wherein the first gate structure covers a first portion of the STI region. The second gate structure is over the second active region and within the first trench. Wherein the second gate structure covers a second portion of the STI region; and a distance between the first gate structure and the second gate structure is decided by the inserting dielectric layer.

According to one embodiment of the present disclosure, the MOS transistor structure further includes a first source region and a first drain region electrically contacting to a first channel within the first active region; and a second source region and a second drain region electrically contacting to a second channel within the second active region. Moreover, a width of the inserting dielectric layer between the first active region and the second active region is not defined by a photolithographic process.

Yet another object of the present disclosure is to provide a MOS transistor structure, wherein the MOS transistor structure includes a first fin structure, a second fin structure adjacent to the first fin structure; an inserting dielectric layer, an inserting dielectric layer, a first trench, a second trench, a first gate structure and a second gate structure. The first fin structure and the second fin structure are formed in a semiconductor substrate, wherein a STI region is between the first fin structure and the second fin structure. The inserting dielectric layer is disposed between the first fin structure and the second fin structure. The first trench is surrounding or over the first fin structure, wherein the first trench is adjacent to one side of the inserting dielectric layer. The second trench is surrounding or over the second fin structure, wherein the second trench is adjacent to another side of the inserting dielectric layer. The first gate structure is over the first fin structure and within the first trench, wherein the first gate structure covers a first portion of the STI region. The second gate structure is over the second fin structure and within the first trench. Wherein the second gate structure covers a second portion of the STI region; and a bottom of the inserting dielectric layer is lower than that of the first portion of the STI region or the second portion of the STI region.

According to one embodiment of the present disclosure, the MOS transistor structure further includes a first source region and a first drain region electrically contacting to a first channel within the first fin structure; and a second source region and a second drain region electrically contacting to a second channel within the second fin structure.

### BRIEF DESCRIPTION OF THE DRAWINGS

The above and other aspects of the disclosure will become better understood with regard to the following detailed description of the preferred but non-limiting embodiment(s). The following description is made with reference to the accompanying drawings:

FIG. 1 is a diagram illustrating a FinFET according to the prior art;

FIG. 2A(1) is a top view illustrating the structure after the fin structures are defined in the semiconductor substrate;

FIG. 2A(2) is a cross-sectional view taken along the cutting line C2A1 as depicted in FIG. 2A(1);

FIG. 2A(3) is a cross-sectional view taken along the cutting line C2A2 as depicted in FIG. 2A(1);

FIG. 2B(1) is a top view illustrating the structure after the capping dielectric layer is formed to cover the fin structures;

FIG. 2B(2) is a cross-sectional view taken along the cutting line C2B1 as depicted in FIG. 2B(1);

FIG. 2B(3) is a cross-sectional view taken along the cutting line C2B2 as depicted in FIG. 2B(1);

FIG. 2C(1) is a top view illustrating the structure after the fin structures are partially exposed from the gate opening;

FIG. 2C(2) is a cross-sectional view taken along the cutting line C2C1 as depicted in FIG. 2C(1);

FIG. 2C(3) is a cross-sectional view taken along the cutting line C2B2 as depicted in FIG. 2C(1);

FIG. 2D(1) is a top view illustrating the structure after the epitaxial semiconductor material is formed;

FIG. 2D(2) is a cross-sectional view taken along the cutting line C2D1 as depicted in FIG. 2D(1);

FIG. 2E(1) is a top view illustrating the structure after the gate opening is filed by a dielectric layer;

FIG. 2E(2) is a cross-sectional view taken along the cutting line C2E1 as depicted in FIG. 2E(1);

FIG. 2F(1) is a top view illustrating the structure after the gate structures are formed;

FIG. 2F(2) is a cross-sectional view taken along the cutting line C2F1 as depicted in FIG. 2F(1);

FIG. 2F(3) is a cross-sectional view taken along the cutting line C2F2 as depicted in FIG. 2F(1);

FIG. 2G is a perspective view illustrating a semiconductor device with two adjacent MOS transistors formed by the method as shown in FIGS. 2A(1) to 2F(3);

FIG. 3A(1) is a top view illustrating the structure after the fin structures are defined in the semiconductor substrate;

FIG. 3A(2) is a cross-sectional view taken along the cutting line C3A1 as depicted in FIG. 3A(1);

FIG. 3A(3) is a cross-sectional view taken along the cutting line C3A2 as depicted in FIG. 3A(1);

FIG. 3B(1) is a top view illustrating the structure after the dielectric layer and the capping dielectric layer are formed;

FIG. 3B(2) is a cross-sectional view taken along the cutting line C3B1 as depicted in FIG. 3B(1);

FIG. 3B(3) is a cross-sectional view taken along the cutting line C2B2 as depicted in FIG. 3B(1);

FIG. 3C(1) is a top view illustrating the structure after the fin structures are partially exposed from the gate opening;

FIG. 3C(2) is a cross-sectional view taken along the cutting line C3C1 as depicted in FIG. 3C(1);

FIG. 3C(3) is a cross-sectional view taken along the cutting line C3C2 as depicted in FIG. 3C(1);

FIG. 3D(1) is a top view illustrating the structure after the gate structures are formed;

FIG. 3D(2) is a cross-sectional view taken along the cutting line C3E1 as depicted in FIG. 3D(1);

FIG. 3D(3) is a cross-sectional view taken along the cutting line C3D2 as depicted in FIG. 3D(1);

FIG. 4A(1) is a top view illustrating the structure after the fin structures are defined in the semiconductor substrate;

FIG. 4A(2) is a cross-sectional view taken along the cutting line C4A1 as depicted in FIG. 4A(1);

FIG. 4A(3) is a cross-sectional view taken along the cutting line C4A2 as depicted in FIG. 4A(1);

FIG. 4B(1) is a top view illustrating the structure after the capping dielectric layer is formed to cover the fin structures;

FIG. 4B(2) is a cross-sectional view taken along the cutting line C4B1 as depicted in FIG. 4B(1);

FIG. 4B(3) is a cross-sectional view taken along the cutting line C2B2 as depicted in FIG. 4B(1);

FIG. 4C(1) is a top view illustrating the structure after the fin structures are partially exposed from the gate opening;

FIG. 4C(2) is a cross-sectional view taken along the cutting line C4C1 as depicted in FIG. 4C(1);

FIG. 4C(3) is a cross-sectional view taken along the cutting line C4B2 as depicted in FIG. 4C(1);

FIG. 4D(1) is a top view illustrating the structure after the epitaxial semiconductor material is formed;

FIG. 4D(2) is a cross-sectional view taken along the cutting line C4D1 as depicted in FIG. 4D(1);

FIG. 4E(1) is a top view illustrating the structure after the gate openings are deepen to expose the semiconductor substrate;

FIG. 4E(2) is a cross-sectional view taken along the cutting line C4E1 as depicted in FIG. 4E(1);

FIG. 4F(1) is a top view illustrating the structure after the gate opening is filed by a dielectric layer;

FIG. 4F(2) is a cross-sectional view taken along the cutting line C4F1 as depicted in FIG. 4F(1);

FIG. 4G(1) is a top view illustrating the structure after the gate structures are formed;

FIG. 4G(2) is a cross-sectional view taken along the cutting line C4G1 as depicted in FIG. 4G(1);

FIG. 4G(3) is a cross-sectional view taken along the cutting line C4G2 as depicted in FIG. 4G(1);

FIG. 5A(1) is a top view illustrating the structure after the fin structures are defined in the semiconductor substrate;

FIG. 5A(2) is a cross-sectional view taken along the cutting line C5A1 as depicted in FIG. 5A(1);

FIG. 5A(3) is a cross-sectional view taken along the cutting line C5A2 as depicted in FIG. 5A(1);

FIG. 5B(1) is a top view illustrating the structure after the portion of the STIs not covered by the fin spacers is removed;

FIG. 5B(2) is a cross-sectional view taken along the cutting line C5B1 as depicted in FIG. 5B(1);

FIG. 5B(3) is a cross-sectional view taken along the cutting line C5B2 as depicted in FIG. 5B(1);

FIG. 5C(1) is a top view illustrating the structure after the dielectric layer and the capping dielectric layer are formed;

FIG. 5C(2) is a cross-sectional view taken along the cutting line C5C1 as depicted in FIG. 5C(1);

FIG. 5C(3) is a cross-sectional view taken along the cutting line C5C2 as depicted in FIG. 5C(1);

FIG. 5D(1) is a top view illustrating the structure after the fin structures are partially exposed from the gate opening;

FIG. 5D(2) is a cross-sectional view taken along the cutting line C5D1 as depicted in FIG. 5D(1);

FIG. 5D(3) is a cross-sectional view taken along the cutting line C5D2 as depicted in FIG. 5D(1);

FIG. 5E(1) is a top view illustrating the structure after the gate structures are formed;

FIG. 5E(2) is a cross-sectional view taken along the cutting line C5E1 as depicted in FIG. 5E(1); and

FIG. 5E(3) is a cross-sectional view taken along the cutting line C5E2 as depicted in FIG. 5E(1).

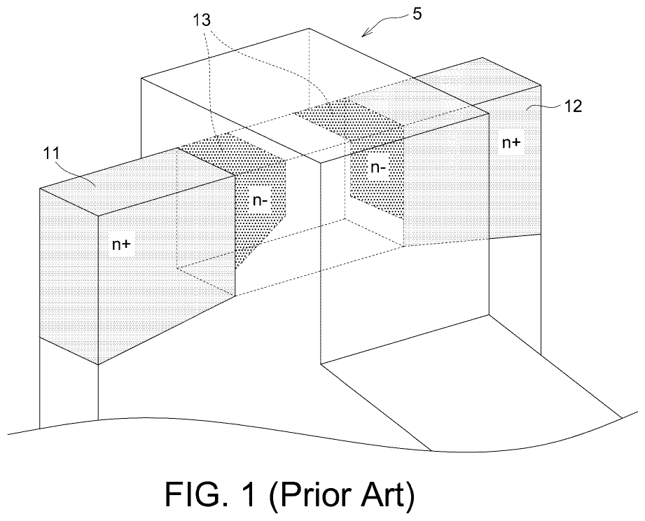

### DETAILED DESCRIPTION OF THE DISCLOSURE

The present disclosure provides a method for forming a semiconductor device with a plurality of the MOS transistors to minimize and well control the pitch between two adjacent gate structures of two adjacent MOS transistors. The above and other aspects of the disclosure will become better understood by the following detailed description of the preferred but non-limiting embodiment(s). The following description is made with reference to the accompanying drawings:

Several embodiments of the present disclosure are disclosed below with reference to accompanying drawings. However, the structure and contents disclosed in the embodiments are for exemplary and explanatory purposes only, and the scope of protection of the present disclosure is not limited to the embodiments. It should be noted that the present disclosure does not illustrate all possible embodiments, and anyone skilled in the technology field of the disclosure will be able to make suitable modifications or changes based on the specification disclosed below to meet actual needs without breaching the spirit of the disclosure. The present disclosure is applicable to other implementations not disclosed in the specification.

### Embodiment 1

The present embodiment discloses a semiconductor device 20 having two MOS transistors T21 and T22 respectively formed based on two adjacent fin structures 201 F1 and 201 F2. Detailed steps of the manufacturing method of the semiconductor device 20 are as follows:
Step S21: A plurality of fin structures 201 F1 and 201 F2 are defined in a semiconductor substrate 201, each of the fin structures 201F1 and 201F2 is surrounded by a fin spacer 207; wherein Step S21 includes Sub-steps S211-S215:
   Sub-step S211: A portion of the semiconductor substrate 201 are removed using a patterned pad dielectric layer 210 (including a patterned pad oxide layer 210A and a patterned pad nitride layer 210B) to defined the fin structures 201 F1 and 201 F2;
   Sub-step S212: A shallow trench isolation (STIs) region 208 is formed surrounding the fin structures 201F1 and 201F2;
   Sub-step S213: An etching back process is performed to remove portions of the shallow trench isolation (STIs) region 208, so as to expose sidewalls of the fin structures 201 F1 and 201 F2; and
   Sub-step S214: A thermal oxidation process is performed to form oxide spacers 207A on the sidewalls of the fin structures 201 F1 and 201 F2; and
   Sub-step S215: A nitride deposition process is performed to form nitride spacers 207B on the oxide spacers 207A;
Step S22: Gate openings 202 are defined in a capping dielectric layer 209 covering the fin structures 201 F1 and 201 F2 and the STIs 208, wherein the sidewalls of each of the fin structures 201F1 and 201F2 are partially exposed from corresponding one of the gate openings 202; Step S22 includes Sub-steps S221-S222:
   Sub-step S221: An oxide deposition process is performed to form the capping dielectric layer 209 on the fin structures 201 F1 and 201 F2;
   Sub-step S222: A patterned process is performed to remove a portion of the capping dielectric layer 209 to define the gate opening 202, from which the nitride spacers 207B are exposed; and
   Sub-step S223: The nitride spacers 207B and the oxide spacers 207A within the gate opening 202 are removed, so as to make each of the fin structures 201F1 and 201F2 partially exposed from the gate opening 202;
Step S23: Epitaxial semiconductor material 203 (serving as a sacrificial spacer) are formed based on the exposed portions of the fin structures 201 F1 and 201 F2;
Step S24: The gate openings 202 are filed by an inserting dielectric layer 211 to surround the epitaxial semiconductor material 203;
Step S25: The epitaxial semiconductor material 203 is removed to expose the exposed portions 201 E1 and 201 E2 of the fin structures 201 F1 and 201 F2 again; and
Step S26: gate structures 204 and 205 are formed respectively on the fin structures 201F1 and 201F2; wherein Step S26 includes Sub-steps S261-S262:
   Sub-step S261: The nitride spacers 207B and the oxide spacers 207A are removed to expose the fin structures 201 F1 and 201 F2;
   Sub-step S262: Gate dielectric layers 204O and 205O are formed respectively covering the tops and sidewalls of the fin structures 201 F1 and 201 F2; and
   Sub-step S263: Gate electrodes 204S and 205S are formed respectively covering the gate oxide layers 204O and 205O.

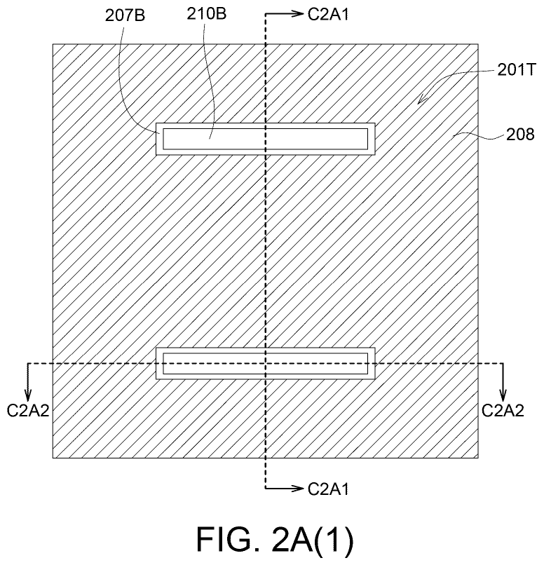

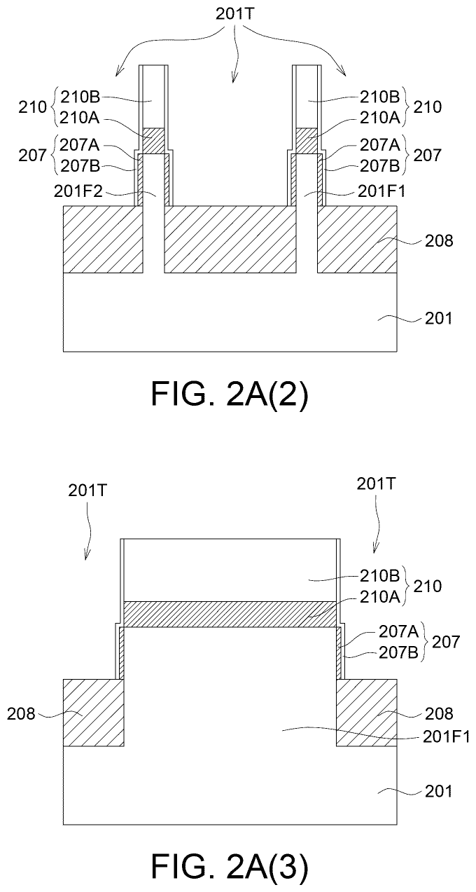

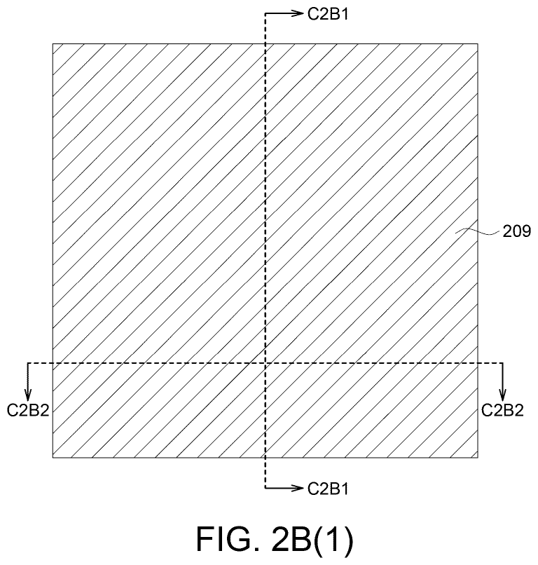

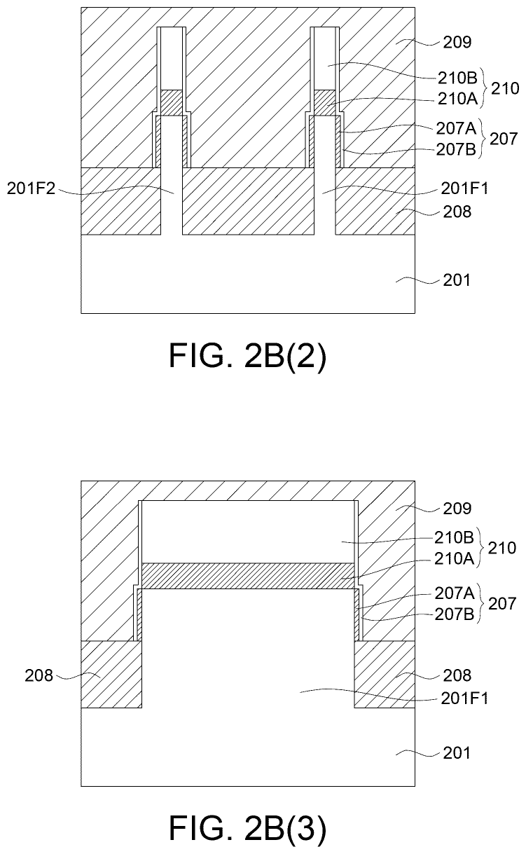

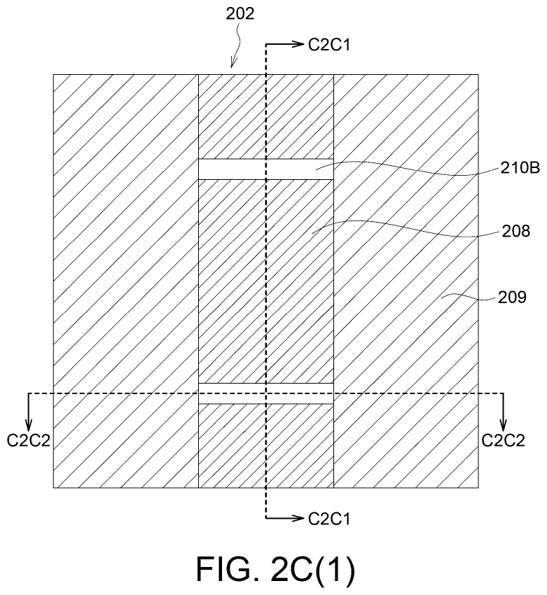

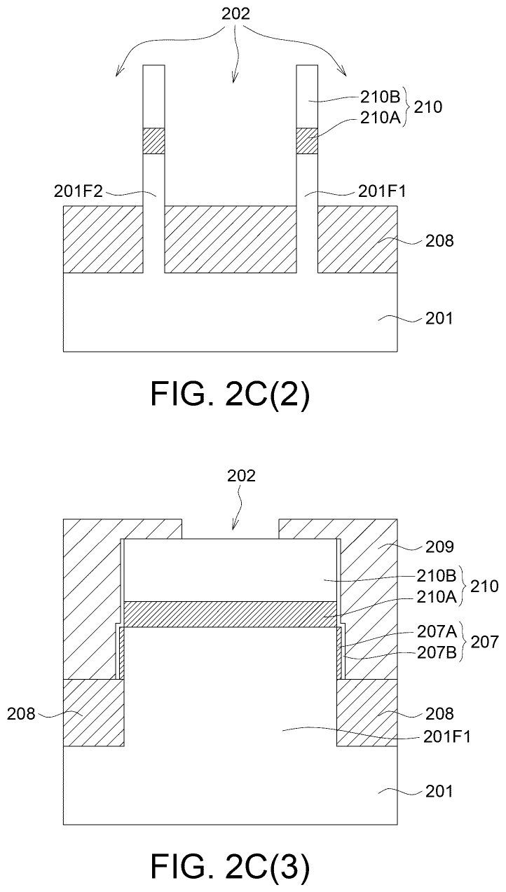

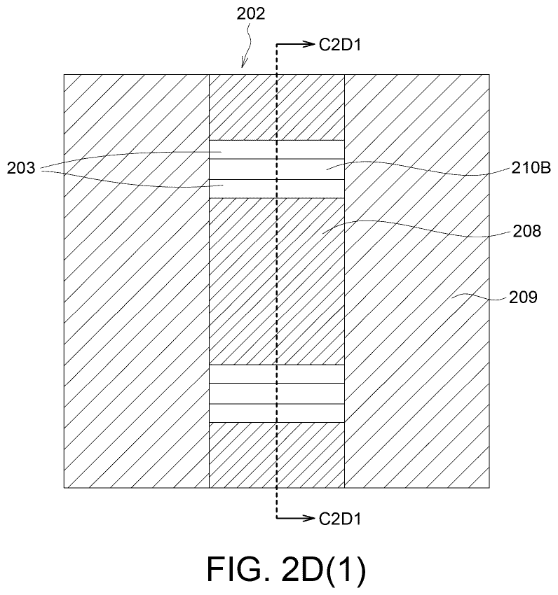

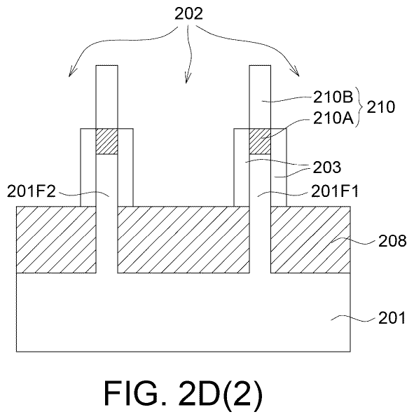

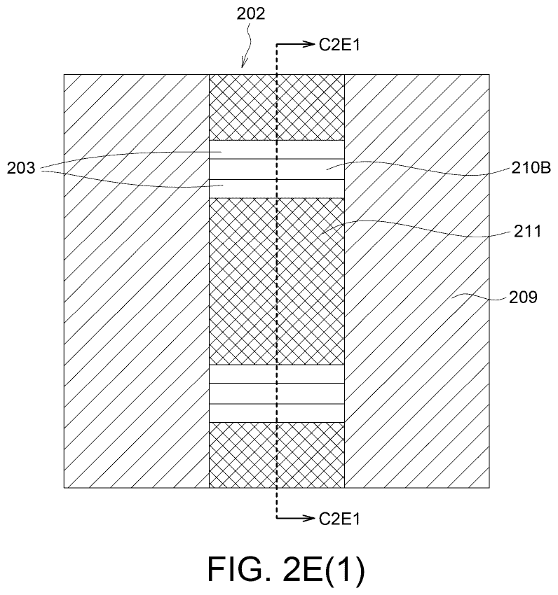

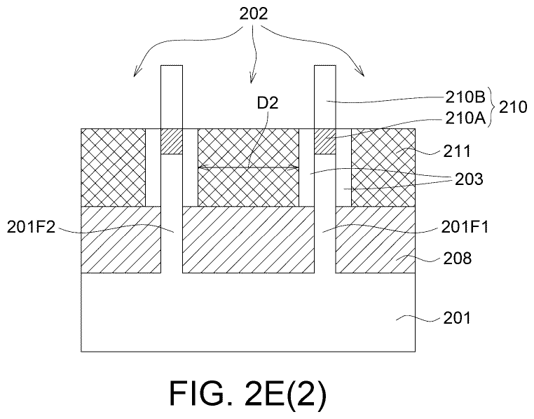

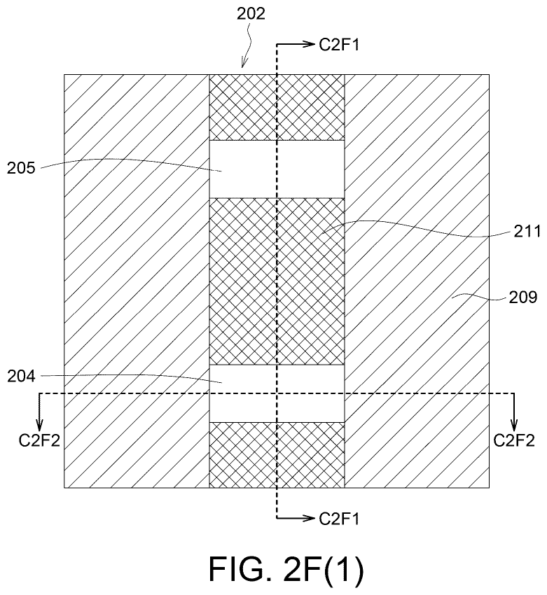

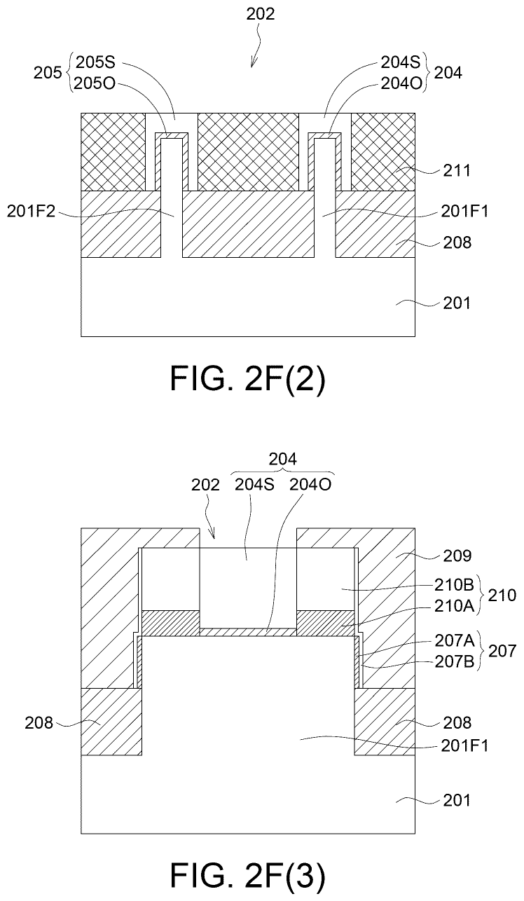

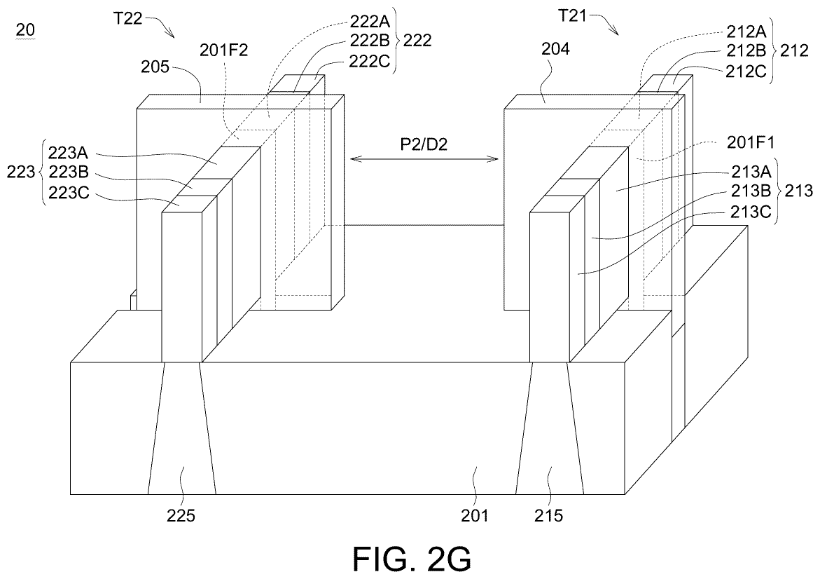

Referring to Step S21, a plurality of fin structures 201 F1 and 201 F2 are defined in a semiconductor substrate 201, each of the fin structures 201 F1 and 201 F2 is surrounded by a fin spacer 207. Referring to FIGS. 2A(1) to 2A(3), FIG. 2A(1) is a top view illustrating the structure after the fin structures 201 F1 and 201F2 are defined in the semiconductor substrate 201; FIG. 2A(2) is a cross-sectional view taken along the cutting line C2A1 as depicted in FIG. 2A(1); and FIG. 2A(3) is a cross-sectional view taken along the cutting line C2A2 as depicted in FIG. 2A(1). The fin structures 201F1 and 201F2 are defined by Sub-Steps S211-S215 as follows:

Referring to sub-step S211: An etching process using a patterned pad dielectric layer 210 (including a patterned pad oxide layer 210A and a patterned pad nitride layer 210B) as an etching mask is performed to remove parts of silicon material of a semiconductor substrate 201 to create trenches 201T and define a plurality of fin structures 201F1 and 201F2 in the semiconductor substrate 201. In some embodiments, the distance of the adjacent two fin structures 201 F1 and 201F2 may be about 30-50 nm. Each of the fin structures 201F1 and 201F2 has a thickness about 3-10 nm, such as 5 nm.

Referring to sub-step S212: a shallow trench isolation (STIs) region 208 is formed surrounding the fin structures 201F1 and 201F2. In some embodiments of the present disclosure, oxide material is deposited to fully fill the trenches 201T and then etched back, such that the oxide material remained in the trenches 201T can serve as STIs region 208 surrounding the plurality of fin structures 201F1 and 201F2. Referring to Sub-step S213: an etching back process is performed to remove portions of the shallow trench isolation (STIs) region 408, so as to expose sidewalls of the fin structures 201F1 and 201F2.

Next, referring to sub-step S214: A thermal oxidation process is performed to form the oxide spacers 207A on the sidewalls of the fin structures 201F1 and 201F2; and referring to sub-step S215: A nitride deposition process is performed to form the nitride spacers 207B on the oxide spacers 207A (as shown in FIGS. 2A(2) and 2A(3)).

Referring to step S22: Gate openings 202 are defined in a capping dielectric layer 209 covering the fin structures 201 F1 and 201 F2 and the STIs region 208, wherein the sidewalls of each of the fin structures 201 F1 and 201 F2 are partially exposed from corresponding one of the gate openings 202; wherein Step S22 includes Sub-steps S221-S222:

Referring to Sub-step S221: An oxide deposition process is performed to form the capping dielectric layer 209 on the fin structures 201 F1 and 201 F2. See FIGS. 2B(1) to 2B(3), FIG. 2B(1) is a top view illustrating the structure after the capping dielectric layer 209 is formed to cover the fin structures 201 F1 and 201 F2; FIG. 2B(2) is a cross-sectional view taken along the cutting line C2B1 as depicted in FIG. 2B(1); and FIG. 2B(3) is a cross-sectional view taken along the cutting line C2B2 as depicted in FIG. 2B(1). In the present embodiment, the oxide deposition process for forming the capping dielectric layer 209 is followed by a planarization process; and the capping dielectric layer 209 includes silicon dioxide (SiO₂).

Referring to Sub-step S222: a patterned process is performed to remove a portion of the capping dielectric layer 209 to define the gate opening 202, from which the nitride spacers 207B are exposed. Referring to Sub-step S223: the nitride spacers 207B and the oxide spacers 207A are then removed respectively by another etching process, so as to make each of the fin structures 201 F1 and 201 F2 partially exposed from the gate opening 202. See FIGS. 2C(1) to 2C(3), FIG. 2C(1) is a top view illustrating the structure after the fin structures 201 F1 and 201 F2 are partially exposed from the gate opening 202; FIG. 2C(2) is a cross-sectional view taken along the cutting line C2C1 as depicted in FIG. 2C(1); and FIG. 2C(3) is a cross-sectional view taken along the cutting line C2B2 as depicted in FIG. 2C(1).

Referring to Step S23: Epitaxial semiconductor material 203 (serving as a sacrificial spacer) are formed based on the exposed portions of the fin structures 401 F1 and 201 F2. See FIGS. 2D(1) and 2D(2), wherein FIG. 2D(1) is a top view illustrating the structure after the epitaxial semiconductor material 203 is formed; and FIG. 2D(2) is a cross-sectional view taken along the cutting line C2D1 as depicted in FIG. 2D(1). In some embodiments of the present disclosure, the epitaxial semiconductor material 203 (such as Si, SiGe, Ge, etc.) is formed by a selective epitaxy growth (SEG) method based on the exposed portions of the fin structures 201F1 and 201F2. In some other embodiments of the present disclosure, depending on the material of the fin structures other semiconductor epitaxial material (such as, SiC, gallium arsenide (GaAs), gallium nitride (GaN), etc.) may be grown based on the exposed portions of the fin structures 201F1 and 201F2. The epitaxial semiconductor material 203 has a thickness about 5-12 nm, such as 7-8 nm.

Next, referring to Step S24: The gate opening 202 is filed by an inserting dielectric layer 211. See FIGS. 2E(1) and 2E(2). FIG. 2E(1) is a top view illustrating the structure after the gate opening 202 is filed by an inserting dielectric layer 211; and FIG. 2E(2) is a cross-sectional view taken along the cutting line C2E1 as depicted in FIG. 2E(1). In some embodiments of the present disclosure, the material constituting the inserting dielectric layer 211 may be different from that constituting the capping dielectric layer 209. In the present embodiment, the inserting dielectric layer 211 is formed by a low-k dielectric material (such as, SiCOH) deposition process. The inserting dielectric layer 211 may be then etched back. Such that, the patterned pad nitride layer 210B (or even the pad oxide layer 210A) can be exposed from the partially filled gate opening 202. Moreover, as shown in FIG. 2E(2), the distance D2 between two epitaxial semiconductor material 203 or sacrificial spacers is around 15-30 nm, such as 20 nm, and the distance D2 could be equal to or substantially equal to the “gate cut” or “poly cut” distance between two gate structures of the adjacent transistors.

Referring to Steps S25: The epitaxial semiconductor material 203 is removed to form vacancies and expose the sidewalls of the fin structures 201 F1 and 201 F2 again; and then referring to Step S26: Gate structures 204 and 205 are formed respectively on the fin structures 201 F1 and 201 F2. See FIGS. 2F(1) and 2F(2). FIG. 2F(1) is a top view illustrating the structure after the gate structures 204 and 205 are formed; FIG. 2F(2) is a cross-sectional view taken along the cutting line C2F1 as depicted in FIG. 2F(1); and FIG. 2F(3) is a cross-sectional view taken along the cutting line C2F2 as depicted in FIG. 2F(1).

The Step S26 for forming the gate structures 204 and 205 includes Sub-steps S261-S262: Referring to Sub-step S461: The nitride spacers 207B and the oxide spacers 207A are removed to expose the fin structures 201 F1 and 201F2. In the present embodiments, the nitride spacers 207B and the oxide spacers 207A are removed by different etching processes respectively.

Next, referring to Sub-step S262: The gate dielectric layers 204O and 205O are formed respectively covering the tops and sidewalls of the fin structures 201F1 and 201F2. In some embodiments of the present disclosure, the gate dielectric layers 204O and 205O are formed by an oxide deposition process. Then, referring to Sub-step S263: The gate electrodes 204S and 205S are formed respectively covering the gate dielectric layers 204O and 205O. In some embodiments of the present disclosure, the gate electrodes 204S and 205S are formed by polysilicon or metal. Thus, the vacancies formed after the epitaxial semiconductor material 203 is removed are just be filled with the gate dielectric layers 204O and 205O and the gate electrodes 204S and 205S.

After the forming of the gate structures 204 and 205, the source/drain regions for the transistors could be formed. For example, remove portion of fin structures outside the gate regions, localized isolations 215 and 225 are (optionally) then formed in the semiconductor substrate 201. The source region 212 including an LDD region (e.g. N− semiconductor region) 212A, a N+ semiconductor region 212B and a landing pad 212C, as well as the drain region 213 including an LDD region (e.g. N− semiconductor region) 213A, a N+ semiconductor region 213B and a landing pad 213C are formed over the localized isolations 215 and electrically contact to the fin structure 201F1, wherein the landing pads 212C (or 213C) may contact the most lateral sidewall of the N+ semiconductor region 212B (or 213B). Similarly, the source region 222 including an LDD region (e.g. N− semiconductor region) 222A, a N+ semiconductor region 222B and a landing pad 222C, as well as the drain region 223 including an LDD region (e.g. N− semiconductor region) 223A, a N+ semiconductor region 223B and a landing pad 223C are formed over the localized isolations 225 and electrically contact to the fin structure 201 F2. Such that, the semiconductor device 20 (see FIG. 2G) with two adjacent MOS transistors T21 and T22 are formed and separated from each other for a certain gate electrode pitch P2 (or called as “gate cut” distance or “poly cut” distance), wherein the gate electrode pitch P2 can be equal to the certain distance D2 that is defined by the portion of the dielectric material 211 disposed between the two adjacent fin structures 201 F1 and 201 F2.

After a series steps of down-stream process are performed, the forming of the semiconductor device 20 (such as, a SRAM cell) applying the MOS transistors T21 and T22 can be implemented. Since, the certain distance D2 can be well controlled by the dielectric material 211 deposited into the gate opening 202, which is far less than the traditional lithography rule used to define the gate electrode pitch of two adjacent MOS transistors, thus the gate electrode pitch P2 between two adjacent MOS transistors T21 and T22 can be significant minimized.

In addition, since the fin structures 201F1 and 201F2 can be protected by the fin spacer 207 prior to gate and source/drain formation, and be well supported by the first dielectric material 209, thus it can prevent the fin structures 201F1 and 201F2 from been collapsed during the process for forming the gate structures 204 and 205, the source region 212/222 and the drain region 213/223.

### Embodiment 2

The present embodiment discloses another semiconductor device 30 having two MOS transistors T31 and T32 respectively formed based on two adjacent fin structures 301 F1 and 301 F2. Detailed steps of the manufacturing method of the semiconductor device 30 are as follows:
Step S31: A plurality of fin structures 301 F1 and 301 F2 are defined in a semiconductor substrate 301, each of the fin structures 301F1 and 301F2 is surrounded by a fin spacer 307; wherein Step S31 includes Sub-steps S311-S313:
   Sub-step S311: A portion of the semiconductor substrate 301 are removed using a patterned pad dielectric layer 310 (including a patterned pad oxide layer 310A and a patterned pad nitride layer 310B) to defined the fin structures 301 F1 and 301 F2;
   Sub-step S312: A shallow trench isolation (STIs) 308 is formed surrounding the fin structures 301 F1 and 301 F2;
   Sub-step S313: An etching back process is performed to remove portions of the shallow trench isolation (STIs) 308, so as to expose sidewalls of the fin structures 301 F1 and 301 F2; and
   Sub-step S314: A thermal oxidation process is performed to form oxide spacers 307A on the sidewalls of the fin structures 301 F1 and 301 F2;
   Sub-step S315: A nitride deposition process is performed to form nitride spacers 307B on the oxide spacers 307A; and
   Sub-step S316: Amorphous silicon spacers 307C (serving as a sacrificial spacer) are formed on the nitride spacers 307B;
Step S32: Gate openings 302 are defined in a capping dielectric layer 309 covering the fin structures 301 F1 and 301 F2 and the STIs 308, wherein the sidewalls of each of the fin structures 301F1 and 301F2 are partially exposed from corresponding one of the gate openings 302. Step S32 includes Sub-steps S321-S324:
   Sub-step S321: An inserting dielectric layer 311 is formed to surround the sidewalls of the fin structures 301 F1 and 301 F2;
   Sub-step S322: An oxide deposition process is performed to form the capping dielectric layer 309 on the fin structures 301F1 and 301F2 and the inserting dielectric layer 311;
   Sub-step S323: A patterned process is performed to remove a portion of the capping dielectric layer 309 to define the gate opening 302; and
   Sub-step S324: the amorphous silicon spacers 307C, the nitride spacers 307B and the oxide spacers 307A are removed, so as to make each of the fin structures 301F1 and 301F2 partially exposed from the gate opening 302;
Step S33: Gate structures 304 and 305 are formed respectively on the fin structures 301F1 and 301F2; wherein Step S33 includes Sub-steps S331-S332:
   Sub-step S331: Gate dielectric layers 3040 and 3050 are formed respectively covering the tops and sidewalls of the fin structures 301 F1 and 301 F2; and
   Sub-step S332: Gate electrodes 304S and 305S are formed respectively covering the gate oxide layers 3040 and 3050.

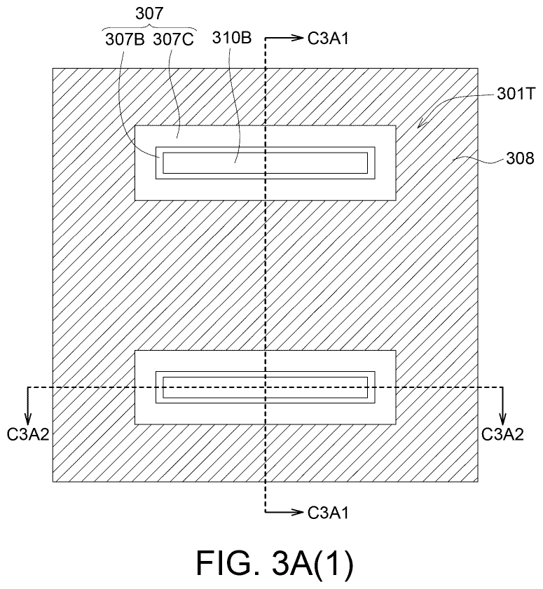

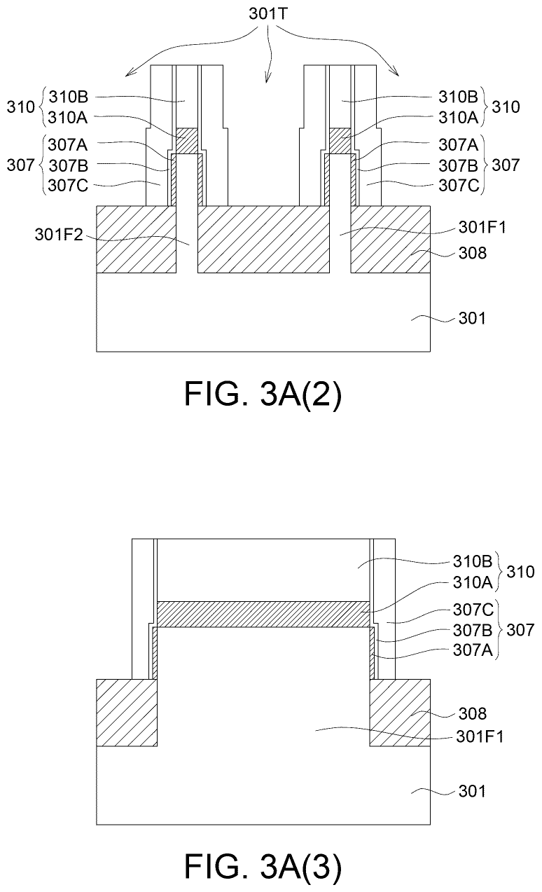

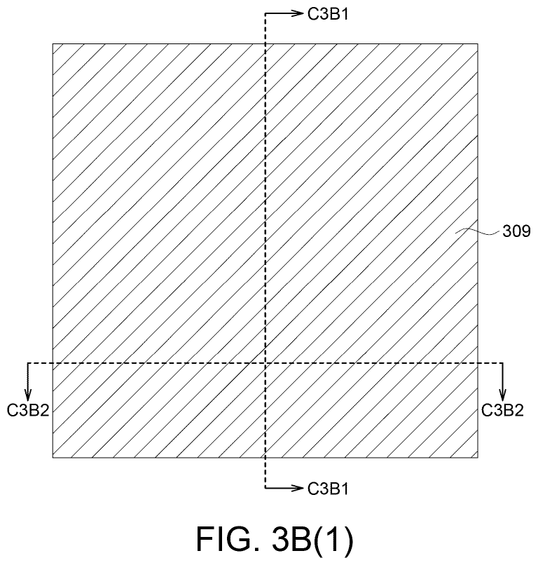

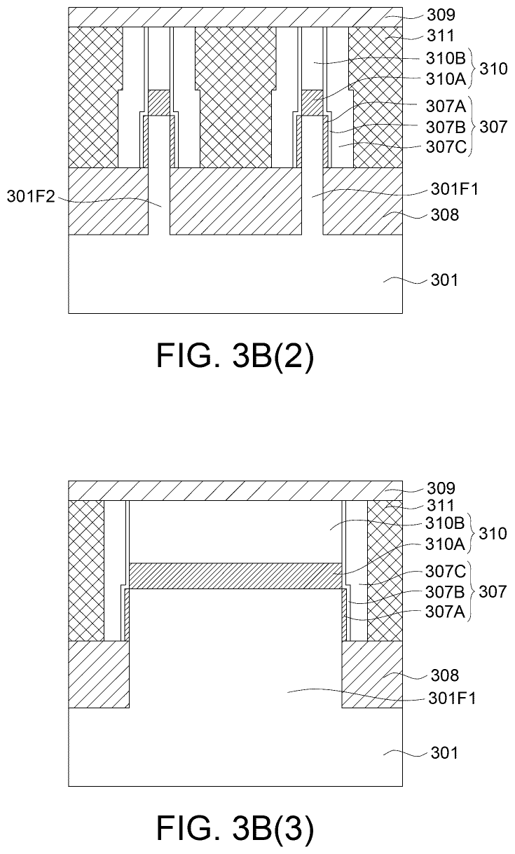

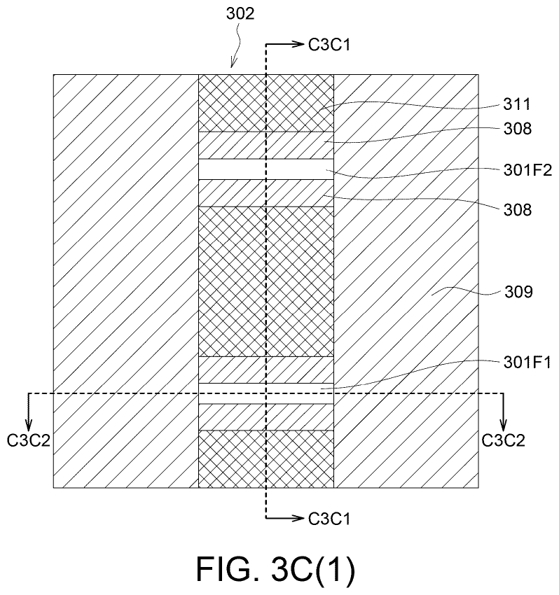

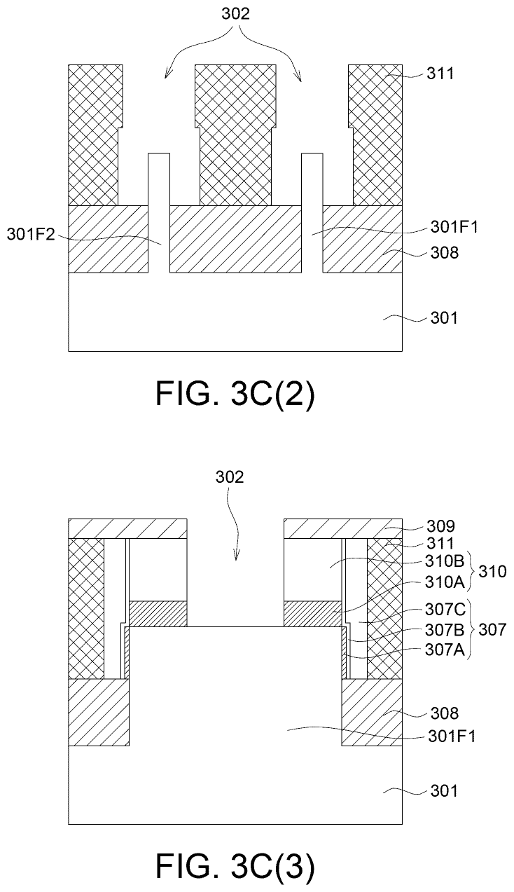

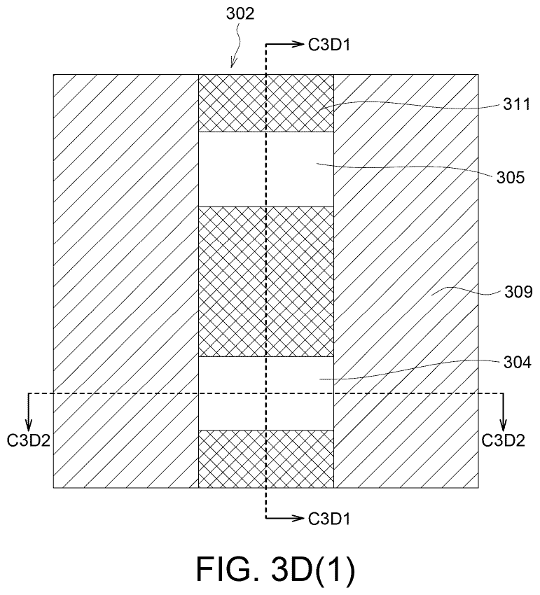

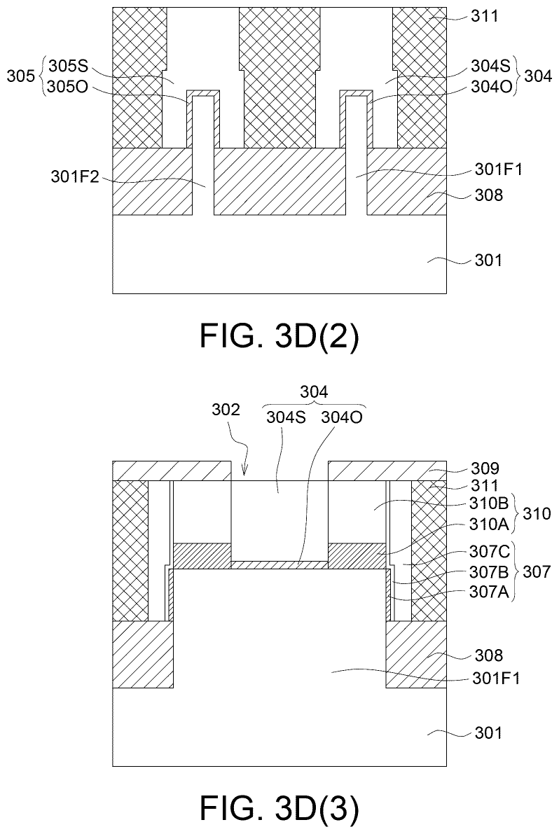

Referring to Step S31, a plurality of fin structures 301 F1 and 301F2 are defined in a semiconductor substrate 301, each of the fin structures 301 F1 and 301F2 is surrounded by a fin spacer 307. See FIGS. 3A(1) to 3A(3), FIG. 3A(1) is a top view illustrating the structure after the fin structures 301 F1 and 301F2 are defined in the semiconductor substrate 301; FIG. 3A(2) is a cross-sectional view taken along the cutting line C3A1 as depicted in FIG. 3A(1); and FIG. 3A(3) is a cross-sectional view taken along the cutting line C3A2 as depicted in FIG. 3A(1). The fin structures 301F1 and 301F2 are defined by Sub-Steps S311-S315 as follows:

Referring to sub-step S311: An etching process, using a patterned pad dielectric layer 310 (including a patterned pad oxide layer 310A and a patterned pad nitride layer 310B) as an etching mask, is performed to remove parts of silicon material of a semiconductor substrate 301 to create trenches 301T and define a plurality of fin structures 301F1 and 301F2 in the semiconductor substrate 301. In some embodiments, the distance of the adjacent two fin structures 301 F1 and 301 F2 may be about 30-50 nm. Each of the fin structures 301F1 and 301F2 has a thickness about 3-10 nm, such as 5 nm.

Referring to sub-step S312: a shallow trench isolation (STIs) 308 is formed surrounding the fin structures 301F1 and 301F2. In some embodiments of the present disclosure, oxide material is deposited to fully fill the trenches 301T and then etched back, such that the oxide material remained in the trenches 301T can serve as STIs 308 surrounding the plurality of fin structures 301F1 and 301F2. Referring to Sub-step S313: An etching back process is performed to remove portions of the shallow trench isolation (STI) regions 308, so as to expose sidewalls of the fin structures 301 F1 and 301 F2.

Next, referring to sub-step S314: A thermal oxidation process is performed to form the oxide spacers 307A on the sidewalls of the fin structures 301F1 and 301F2. Then referring to sub-step S315: A nitride deposition process is performed to form the nitride spacers 307B on the oxide spacers 307A. And referring to sub-step S316: Amorphous silicon spacers 307C (serving as a sacrificial spacer) are formed on the nitride spacers 307B. In some embodiments of the present disclosure, the forming of the amorphous silicon spacers 307C includes steps of depositing amorphous silicon to cover the fin spacer 307, the shallow trench isolation (STIs) 308 and the fin structures 301 F1 and 301 F2; and performing an anisotropic etching process to removing portions of the amorphous silicon and to remain the portion of the amorphous silicon disposed on the sidewalls of the nitride spacers 307B. Each of the amorphous silicon spacers 307C has a thickness about 5-10 nm.

Referring to step S32: Gate openings 302 are defined in a capping dielectric layer 309 covering the fin structures 301 F1 and 301 F2 and the STIs 308, wherein the sidewalls of each of the fin structures 301 F1 and 301 F2 are partially exposed from corresponding one of the gate openings 302. Wherein Step S32 includes Sub-steps S321-S324:

Referring to Sub-step S321: An inserting dielectric layer 311 is formed to surround the sidewalls of the fin structures 301 F1 and 301 F2, and referring to Sub-step S322: An oxide deposition process is performed to form the capping dielectric layer 309 on the fin structures 301 F1 and 301 F2 and the inserting dielectric layer 311. See FIGS. 3B(1) to FIG. 3B(3), FIG. 3B(1) is a top view illustrating the structure after the inserting dielectric layer 311 and the capping dielectric layer 309 are formed; FIG. 3B(2) is a cross-sectional view taken along the cutting line C3B1 as depicted in FIG. 3B(1); and FIG. 3B(3) is a cross-sectional view taken along the cutting line C2B2 as depicted in FIG. 3B(1).

In some embodiments of the present disclosure, the material constituting the inserting dielectric layer 311 may be different from that constituting the capping dielectric layer 309. In the present embodiment, the inserting dielectric layer 311 is formed by a low-k dielectric material (such as, SiCOH) deposition process to filling in the trenches 301T. The deposited low-k dielectric material may be planarized by a chemical-mechanical polishing (CMP), and then etched backed by using the pad nitride layer 310B, nitride spacers 307B and the amorphous silicon spacers 307C as an etching stop layer. Such that, the pad nitride layer 310B, nitride spacers 307B and the amorphous silicon spacers 307C can be exposed from the partially filled trenches 301T. Sub-step S322: the oxide deposition process for forming the capping dielectric layer 309 includes depositing SiO₂ to cover the pad nitride layer 310B, nitride spacers 307B and the amorphous silicon spacers 307C, and is followed by a planarization process (such as, CMP).

Referring to Sub-step S323: A patterned process is performed to remove a portion of the capping dielectric layer 309 to define the gate opening 302. In some embodiment, a patterned photoresist layer (not shown) is formed on the capping dielectric layer 309 to expose the portion of the capping dielectric layer 309 covering the fin structures 301F1 and 301 F2. Then, an etching process is performed to remove the exposed portion of the capping dielectric layer 309 to define the gate opening 302 in the capping dielectric layer 309.

Referring to Sub-step S324: the amorphous silicon spacers 307C, the nitride spacers 307B and the oxide spacers 307A are removed, so as to make each of the fin structures 301F1 and 301F2 partially exposed from the gate opening 302. See FIGS. 3C(1) to FIG. 3C(3), FIG. 3C(1) is a top view illustrating the structure after the fin structures 301F1 and 301F2 are partially exposed from the gate opening 302; FIG. 3C(2) is a cross-sectional view taken along the cutting line C3C1 as depicted in FIG. 3C(1); and FIG. 3C(3) is a cross-sectional view taken along the cutting line C3C2 as depicted in FIG. 3C(1).

In the present embodiment, after the gate opening 302 is defined in the capping dielectric layer 309, another etching process is then performed to remove the amorphous silicon spacers 307C. After the patterned photoresist layer is peered, yet another process is performed remove the nitride spacers 307B and the portion of the patterned pad nitride 310B from the gate opening 302. Next, the oxide spacers 307A and the portion of the patterned pad oxide layer 310A exposed from the gate opening 302 are removed by another etching process, so as to expose the tops and sidewalls of each fin structures 301F1 and 301F2.

Referring to Steps S33: Gate structures 304 and 305 are formed respectively on the fin structures 301F1 and 301F2. See FIGS. 3D(1) to 3D(3). FIG. 3D(1) is a top view illustrating the structure after the gate structures 304 and 305 are formed; FIG. 3D(2) is a cross-sectional view taken along the cutting line C3E1 as depicted in FIG. 3D(1); and FIG. 3D(3) is a cross-sectional view taken along the cutting line C3D2 as depicted in FIG. 3D(1).

The Step S33 for forming the gate structures 304 and 305 includes Sub-steps S331-S332: Referring to Sub-step S331: The gate dielectric layers 3040 and 3050 are formed respectively covering the tops and sidewalls of the fin structures 301F1 and 301F2. In some embodiments of the present disclosure, the gate dielectric layers 3040 and 3050 are formed by an oxide deposition process. Then, referring to Sub-step S332: The gate electrodes 304S and 305S are formed respectively covering the gate dielectric layers 3040 and 3050. In some embodiments of the present disclosure, the gate electrodes 304S and 305S are formed by polysilicon or metal.

After the forming of the gate structures 304 and 305, the capping dielectric layer 309 is then removed, and the source/drain regions could be formed as previously mentioned. Again, since the certain distance can be well controlled by the second dielectric material of the inserting dielectric layer 311 deposited in the gate opening 302, which is far less than the traditional lithography rule used to define the gate electrode pitch of two adjacent MOS transistors, thus the gate electrode pitch between two adjacent MOS transistors T31 and T32 can be significant minimized.

In addition, since the sidewalls of the fin structures 301F1 and 301 F2 can be protected by the fin spacer 307 prior to gate and source/drain formation, and be well supported by the first dielectric material of the capping dielectric layer 309 and the second dielectric material of the inserting dielectric layer 311, thus it can prevent the vulnerable fin structures 301F1 and 301F2 from been collapsed during the process for forming the gate structures 304 and 305, the source region 312/322 and the drain region 313/323.

### Embodiment 3

The present embodiment discloses a semiconductor device 40 having two MOS transistors T41 and T42 respectively formed based on two adjacent fin structures 401 F1 and 401 F2. Detailed steps of the manufacturing method of the semiconductor device 40 are as follows:
Step S41: A plurality of fin structures 401 F1 and 401 F2 are defined in a semiconductor substrate 401, each of the fin structures 401F1 and 401F2 is surrounded by a fin spacer 407; wherein Step S41 includes Sub-steps S411-S415:
   Sub-step S411: A portion of the semiconductor substrate 401 are removed using a patterned pad dielectric layer 410 (including a patterned pad oxide layer 410A and a patterned pad nitride layer 410B) to defined the fin structures 401 F1 and 401 F2;
   Sub-step S412: A shallow trench isolation (STIs) region 408 is formed surrounding the fin structures 401F1 and 401 F2;
   Sub-step S413: An etching back process is performed to remove portions of the shallow trench isolation (STI) regions 408, so as to expose sidewalls of the fin structures 401 F1 and 401 F2; and
   Sub-step S414: A thermal oxidation process is performed to form oxide spacers 407A on the sidewalls of the fin structures 401 F1 and 401 F2; and
   Sub-step S415: A nitride deposition process is performed to form nitride spacers 407B on the oxide spacers 407B;
Step S42: Gate openings 402 are defined in a capping dielectric layer 409 covering the fin structures 401 F1 and 401 F2 and the STIs 408, wherein the sidewalls of each of the fin structures 401F1 and 401F2 are partially exposed from corresponding one of the gate openings 402; wherein Step S42 includes Sub-steps S421-S422:
   Sub-step S421: An oxide deposition process is performed to form the capping dielectric layer 409 on the fin structures 401 F1 and 401 F2;
   Sub-step S422: An patterned process is performed to remove a portion of the capping dielectric layer 409 to define the gate opening 402, from which the nitride spacers 407B are exposed; and
   Sub-step S423: The nitride spacers 407B and the oxide spacers 407B within the gate opening 402 are removed, so as to make each of the fin structures 401F1 and 401F2 partially exposed from the gate opening 402;
Step S43: Epitaxial semiconductor material 403 (serving as a sacrificial spacer) are formed based on the exposed portions of the fin structures 401 F1 and 401 F2;
Step S44: The gate openings 402 are deepen by etching the STI region 408 therein to expose the semiconductor substrate 401;
Step S45: The gate openings 402 are filed by an inserting dielectric layer 411 to surround the epitaxial semiconductor material 403;
Step S46: The epitaxial semiconductor material 403 is removed to expose the exposed portions 401E1 and 401E2 of the fin structures 401F1 and 401F2 again; and
Step S47: gate structures 404 and 405 are formed respectively on the fin structures 401F1 and 401F2.

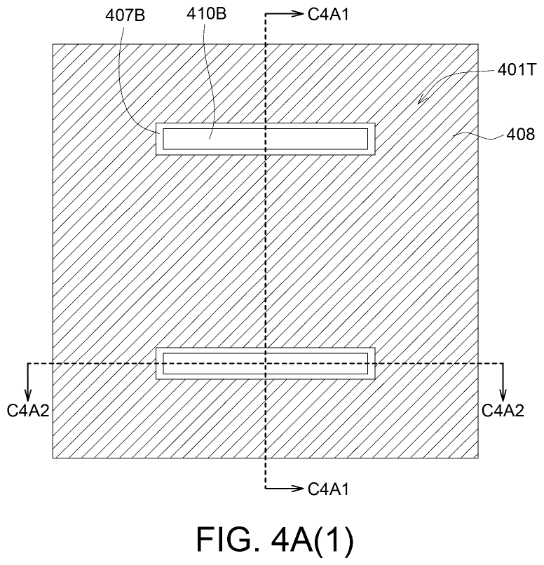

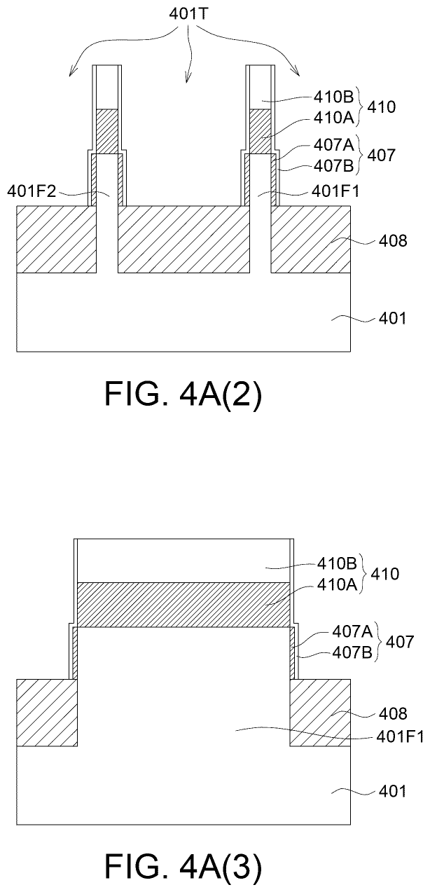

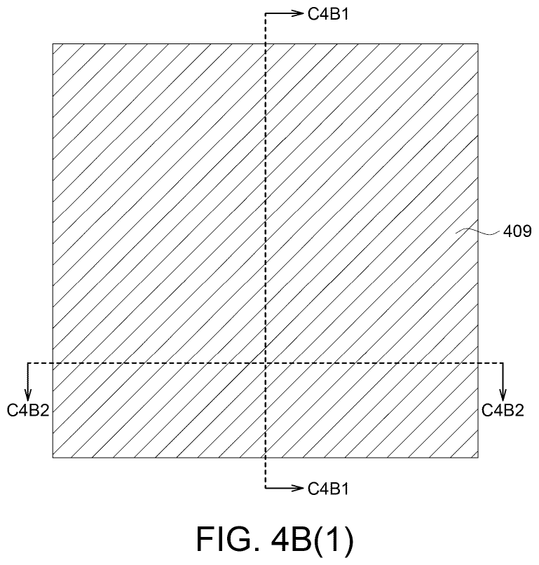

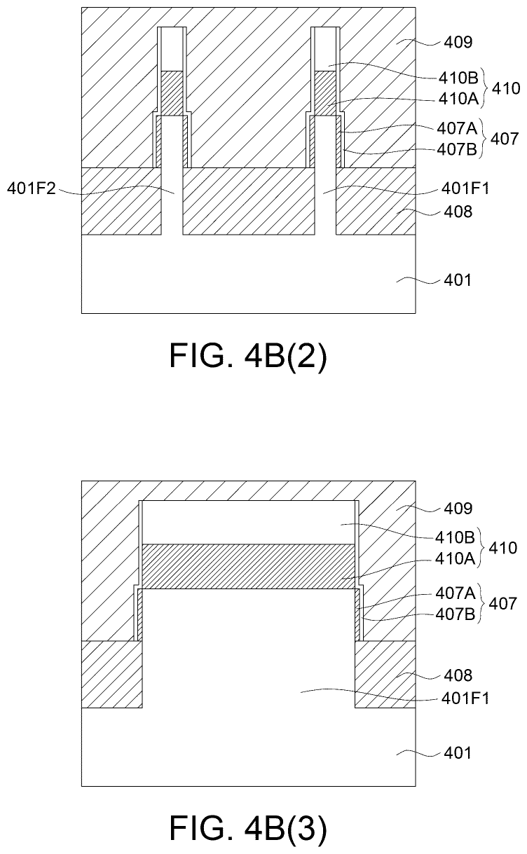

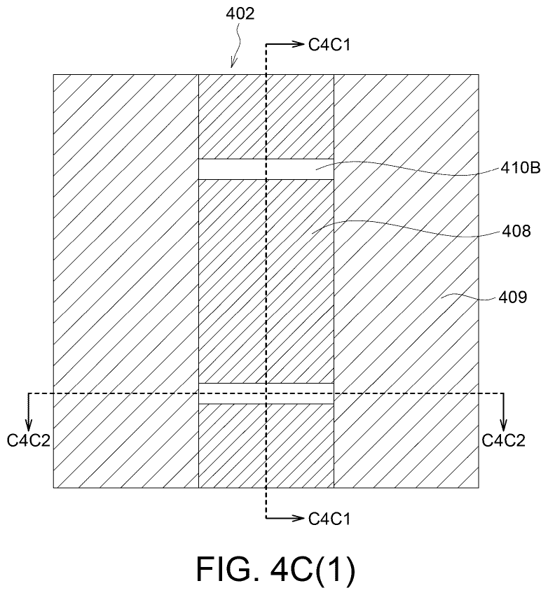

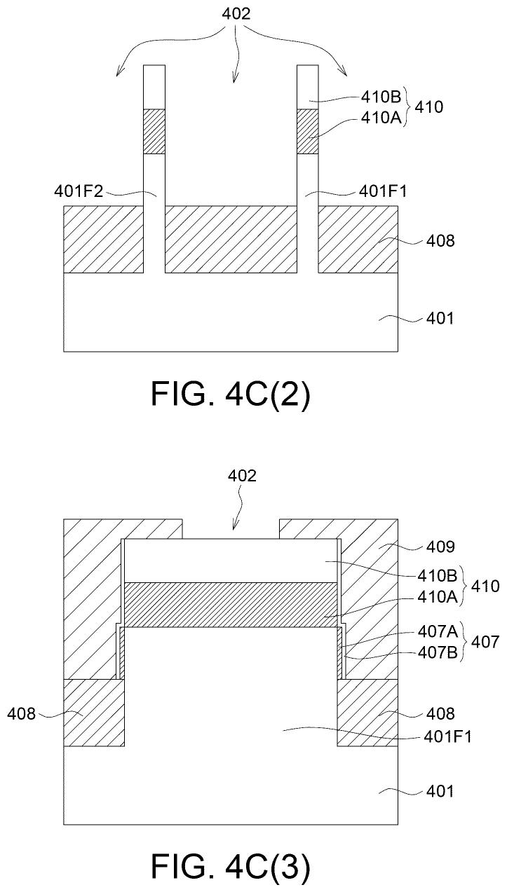

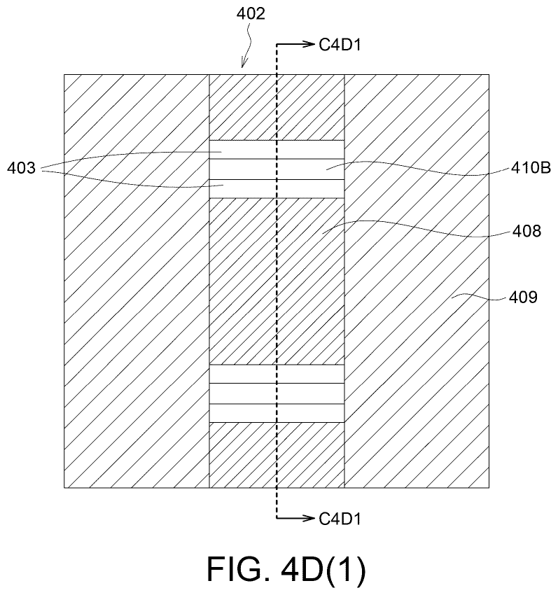

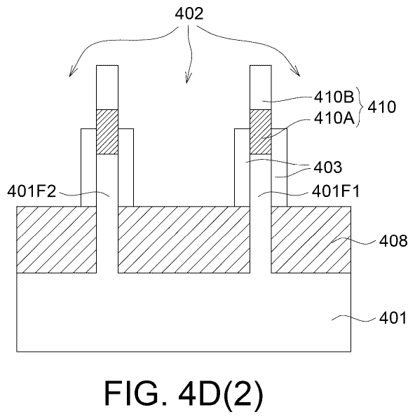

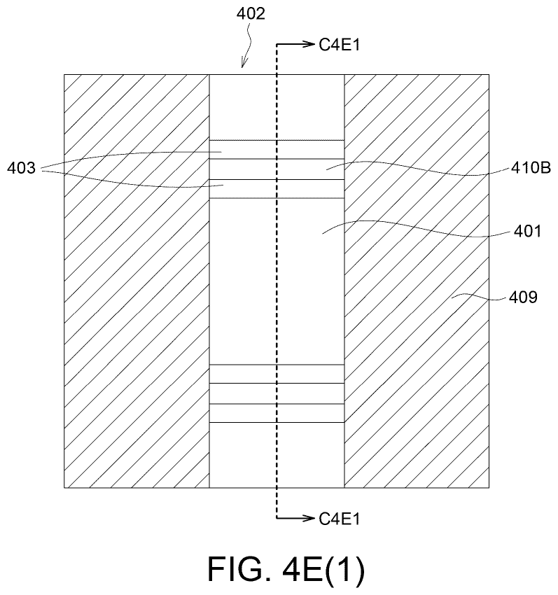

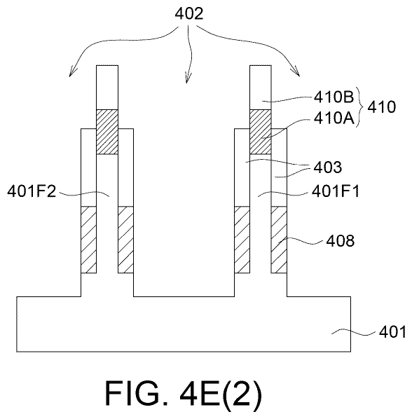

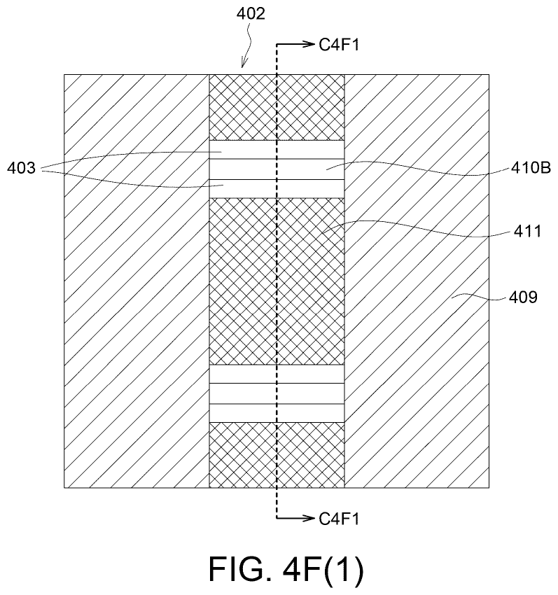

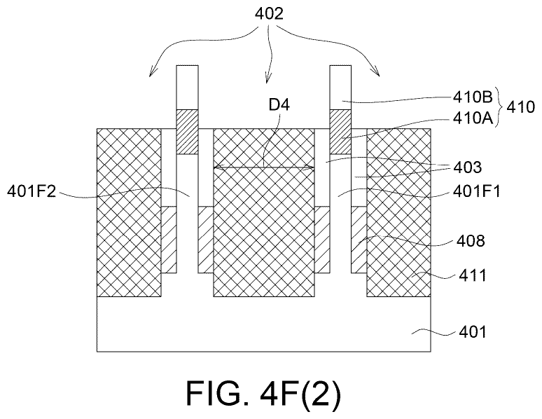

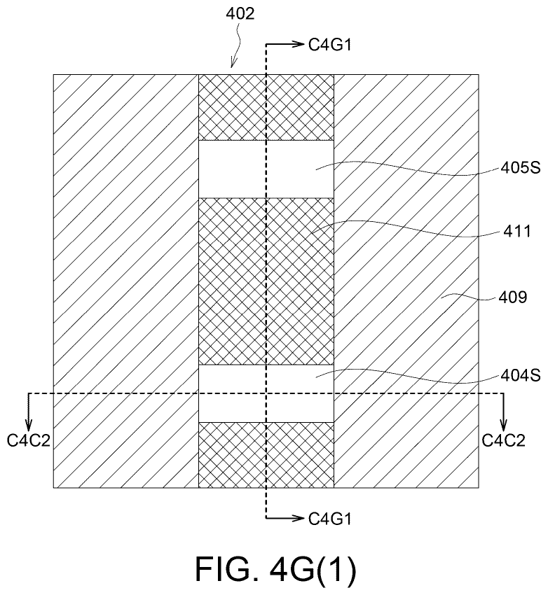

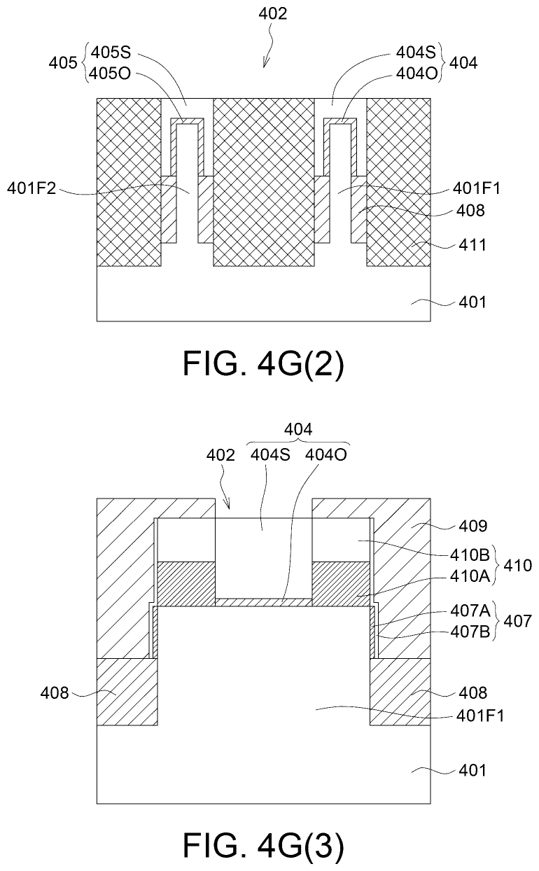

Referring to Step S41, a plurality of fin structures 401F1 and 401F2 are defined in a semiconductor substrate 401, each of the fin structures 401 F1 and 401F2 is surrounded by a fin spacer 407. Referring to FIGS. 4A(1) to 4A(3), FIG. 4A(1) is a top view illustrating the structure after the fin structures 401F1 and 401F2 are defined in the semiconductor substrate 401; FIG. 4A(2) is a cross-sectional view taken along the cutting line C4A1 as depicted in FIG. 4A(1); and FIG. 4A(3) is a cross-sectional view taken along the cutting line C4A2 as depicted in FIG. 4A(1). The fin structures 401F1 and 401F2 are defined by Sub-Steps S411-S415 as follows:

Referring to sub-step S411: An etching process using a patterned pad dielectric layer 410 (including a patterned pad oxide layer 410A and a patterned pad nitride layer 410B) as an etching mask is performed to remove parts of silicon material of a semiconductor substrate 401 to create trenches 401T and define a plurality of fin structures 401F1 and 401F2 in the semiconductor substrate 401. In some embodiments, the distance of the adjacent two fin structures 401F1 and 401F2 may be about 30-50 nm. Each of the fin structures 401F1 and 401F2 has a thickness about 3-10 nm, such as 5 nm.

Referring to sub-step S412: a shallow trench isolation (STI) regions 408 is formed surrounding the fin structures 401F1 and 401F2. In some embodiments of the present disclosure, oxide material is deposited to fully fill the trenches 401T and then etched back, such that the oxide material remained in the trenches 401T can serve as STI regions 408 surrounding the plurality of fin structures 401F1 and 401F2. Referring to Sub-step S413: an etching back process is performed to remove portions of the shallow trench isolation (STI) regions 408, so as to expose sidewalls of the fin structures 401F1 and 401F2.

Next, referring to sub-step S414: A thermal oxidation process is performed to form the oxide spacers 407A on the sidewalls of the fin structures 401 F1 and 401 F2; and referring to sub-step S415: A nitride deposition process is performed to form the nitride spacers 407B on the oxide spacers 407A (as shown in FIGS. 4A(2) and 4A(3)).

Referring to step S42: Gate openings 402 are defined in a capping dielectric layer 409 covering the fin structures 401F1 and 401F2 and the STIs 408, wherein the sidewalls of each of the fin structures 401F1 and 401F2 are partially exposed from corresponding one of the gate openings 402; wherein Step S42 includes Sub-steps S421-S422:

Referring to Sub-step S421: An oxide deposition process is performed to form the capping dielectric layer 209 on the fin structures 201F1 and 401F2. See FIGS. 4B(1) to 4B(3), FIG. 4B(1) is a top view illustrating the structure after the capping dielectric layer 409 is formed to cover the fin structures 401F1 and 401F2; FIG. 4B(2) is a cross-sectional view taken along the cutting line C4B1 as depicted in FIG. 4B(1); and FIG. 4B(3) is a cross-sectional view taken along the cutting line C2B2 as depicted in FIG. 4B(1). In the present embodiment, the oxide deposition process for forming the capping dielectric layer 409 is followed by a planarization process; and the capping dielectric layer 409 includes SiO₂.

Referring to Sub-step S422: a patterned process is performed to remove a portion of the capping dielectric layer 209 to define the gate opening 402, from which the nitride spacers 407B are exposed. Referring to Sub-step S423: the nitride spacers 407B and the oxide spacers 407A are then removed respectively by another etching process, so as to make each of the fin structures 401F1 and 401F2 partially exposed from the gate opening 402. See FIGS. 4C(1) to 4C(3), FIG. 4C(1) is a top view illustrating the structure after the fin structures 401F1 and 401F2 are partially exposed from the gate opening 402; FIG. 4C(2) is a cross-sectional view taken along the cutting line C4C1 as depicted in FIG. 4C(1); and FIG. 4C(3) is a cross-sectional view taken along the cutting line C4B2 as depicted in FIG. 4C(1).

Referring to Step S43: Epitaxial semiconductor material 403 (serving as a sacrificial spacer) are formed based on the exposed portions of the fin structures 401F1 and 401F2. See FIGS. 4D(1) and 4D(2), wherein FIG. 4D(1) is a top view illustrating the structure after the epitaxial semiconductor material 403 is formed; and FIG. 4D(2) is a cross-sectional view taken along the cutting line C4D1 as depicted in FIG. 4D(1). In some embodiments of the present disclosure, the epitaxial semiconductor material 403 (such as Si, SiGe, Ge, etc.) is formed by a SEG method based on the exposed portions of the fin structures 401F1 and 401F2. In some other embodiments of the present disclosure, other semiconductor epitaxial material (such as, GaAs, GaN, SiC, etc.) may be grown based on the exposed portions of the fin structures 401 F1 and 401F2. The epitaxial semiconductor material 403 has a thickness about 5-12 nm, such as 7-8 nm.

Next, referring to Step S44: The gate openings 402 are deepen to expose the semiconductor substrate 401. See FIGS. 4E(1) and 4E(2). FIG. 4E(1) is a top view illustrating the structure after the gate openings 402 are deepen to expose the semiconductor substrate 401; and FIG. 4E(2) is a cross-sectional view taken along the cutting line C4E1 as depicted in FIG. 4E(1). In some embodiments of the present disclosure, an etching process is performed to remove the portion of the STI regions 408 exposed from the gate opening 402 and the portion of the semiconductor substrate 401 beneath the removed portion of the STIs 408.

Thereinafter, referring to Step S45: The gate openings 402 are filed by an inserting dielectric layer 411 to surround the epitaxial semiconductor material 403 and the remained STIs 408. See FIGS. 4F(1) and 4F(2). FIG. 4F(1) is a top view illustrating the structure after the gate opening 402 is filed by an inserting dielectric layer 411; and FIG. 4F(2) is a cross-sectional view taken along the cutting line C4F1 as depicted in FIG. 4F(1). In some embodiments of the present disclosure, the material constituting the inserting dielectric layer 411 may be different from that constituting the capping dielectric layer 409. In the present embodiment, the inserting dielectric layer 411 is formed by a low-k dielectric material (such as, SiCOH) deposition process. The bottom of the inserting dielectric layer 411 (SiCOH) is lower than the bottom of the STIs 408. Since the dielectric constant of the inserting dielectric layer 411 (SiCOH) is lower than that of the STIs 408, therefore, the coupling effect between two gate structures 404 and 406 (which will be formed later, see FIGS. 4G(1) to 4G(3)) could be improved. The inserting dielectric layer 411 may be then etched back. Such that, the patterned pad nitride layer 410B can be exposed from the partially filled gate opening 402. Moreover, as shown in FIG. 4F(2), the distance D4 between two epitaxial semiconductor material 403 or sacrificial spacers is around 15-30 nm, such as 20 nm, and the distance D4 could be equal to or substantially equal to the “gate cut” or “poly cut” distance between two gate structures of the adjacent transistors. The distance D4 could be equal to the width of the inserting dielectric layer 411 between the fin structures 401F1 and 401F2.

Referring to Steps S46: The epitaxial semiconductor material 403 is removed to form vacancies and expose the sidewalls of the fin structures 401F1 and 401F2 again; and then referring to Step S47: Gate structures 404 and 405 are formed respectively on the fin structures 401F1 and 401F2. See FIGS. 4G(1) to 4G(3). FIG. 4G(1) is a top view illustrating the structure after the gate structures 404 and 405 are formed; FIG. 4G(2) is a cross-sectional view taken along the cutting line C4G1 as depicted in FIG. 4G(1); and FIG. 4G(3) is a cross-sectional view taken along the cutting line C4G2 as depicted in FIG. 4G(1).

The Step S47 for forming the gate structures 404 and 405 includes Sub-steps S471-S473: Referring to Sub-step S471: The nitride spacers 407B and the oxide spacers 407A are removed to expose the fin structures 401 F1 and 401F2. In the present embodiments, the nitride spacers 407B and the oxide spacers 407A are removed by different etching processes respectively.

Next, referring to Sub-step S472: The gate dielectric layers 4040 and 4050 are formed respectively covering the tops and sidewalls of the fin structures 401 F1 and 401 F2. In some embodiments of the present disclosure, the gate dielectric layers 4040 and 4050 are formed by an oxide deposition process. Then, referring to Sub-step S473: The gate electrodes 404S and 405S are formed respectively covering the gate dielectric layers 4040 and 4050. In some embodiments of the present disclosure, the gate electrodes 404S and 405S are formed by polysilicon or metal. Thus, the vacancies formed after the epitaxial semiconductor material 403 is removed are just be filled with the gate dielectric layers 4040 and 4050 and the gate electrodes 204S and 205S.

After the forming of the gate structures 404 and 405, the source/drain regions for the transistors could be formed as previously mentioned.

Compared with Embodiment I, in the present embodiment, between two gate structures 404 and 405, the bottom of the inserting dielectric layer 411 (SiCOH) is lower than the bottom of the STIs 408. Since the dielectric constant of the inserting dielectric layer 411 (SiCOH) is lower than that of the STI region 408, therefore, the coupling effect between two gate structures 404 and 405 could be improved.

### Embodiment 4

The present embodiment discloses another semiconductor device 50 having two MOS transistors T51 and T52 respectively formed based on two adjacent fin structures 501F1 and 501F2. Detailed steps of the manufacturing method of the semiconductor device 30 are as follows:
Step S51: A plurality of fin structures 501F1 and 501F2 are defined in a semiconductor substrate 501, each of the fin structures 501F1 and 501F2 is surrounded by a fin spacer 507; wherein Step S51 includes Sub-steps S511-S513:
   Sub-step S511: A portion of the semiconductor substrate 501 are removed using a patterned pad dielectric layer 510 (including a patterned pad oxide layer 510A and a patterned pad nitride layer 510B) to define the fin structures 501F1 and 501F2;
   Sub-step S512: A shallow trench isolation (STI) regions 508 is formed surrounding the fin structures 501F1 and 501F2;
   Sub-step S513: An etching back process is performed to remove portions of the shallow trench isolation (STI) regions 508, so as to expose sidewalls of the fin structures 501F1 and 501F2; and
   Sub-step S514: A thermal oxidation process is performed to form oxide spacers 507A on the sidewalls of the fin structures 501F1 and 501F2;
   Sub-step S515: A nitride deposition process is performed to form nitride spacers 507B on the oxide spacers 507A; and
   Sub-step S516: Amorphous silicon spacers 507C (serving as a sacrificial spacer) are formed on the nitride spacers 507B;
Step S52: The portion of the STIs 508 not covered by the fin spacers 507 (including oxide spacers 507A, the nitride spacers 507B and the amorphous silicon spacers 507C) is removed to expose the portion of the semiconductor substrate 501 beneath the removed portion of the STIs 508;
Step S53: Gate opening 502 is defined in a capping dielectric layer 509 covering the fin structures 501F1 and 501F2 and the STIs 508, wherein the sidewalls of each of the fin structures 501F1 and 501F2 are partially exposed from corresponding one of the gate openings 502; wherein Step S53 includes Sub-steps S531-S534:
   Sub-step S531: An inserting dielectric layer 511 is formed to surround the sidewalls of the fin structures 501F1 and 501F2;
   Sub-step S532: An oxide deposition process is performed to form the capping dielectric layer 509 on the fin structures 501F1 and 501F2 and the inserting dielectric layer 511;
   Sub-step S533: A patterned process is performed to remove a portion of the capping dielectric layer 509 to define the gate opening 502; and
   Sub-step S534: the amorphous silicon spacers 507C, the nitride spacers 507B and the oxide spacers 507A are removed, so as to make each of the fin structures 501F1 and 501F2 partially exposed from the gate opening 502;
Step S54: Gate structures 504 and 505 are formed respectively on the fin structures 501F1 and 501F2; wherein Step S54 includes Sub-steps S541-S542:
   Sub-step S541: Gate dielectric layers 504O and 505O are formed respectively covering the tops and sidewalls of the fin structures 501F1 and 501F2; and
   Sub-step S542: Gate electrodes 504S and 505S are formed respectively covering the gate oxide layers 504O and 505O.

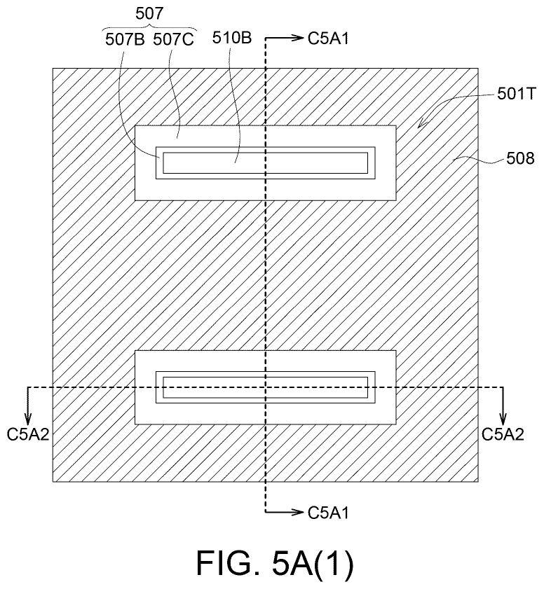

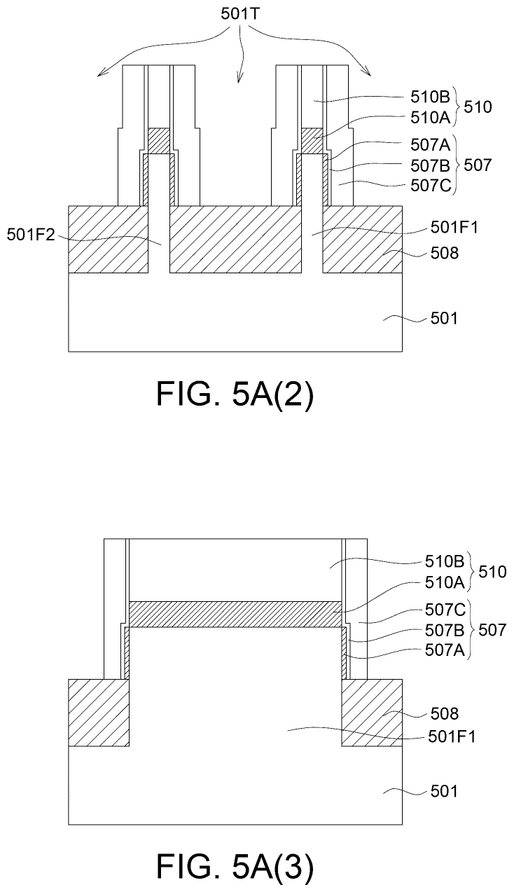

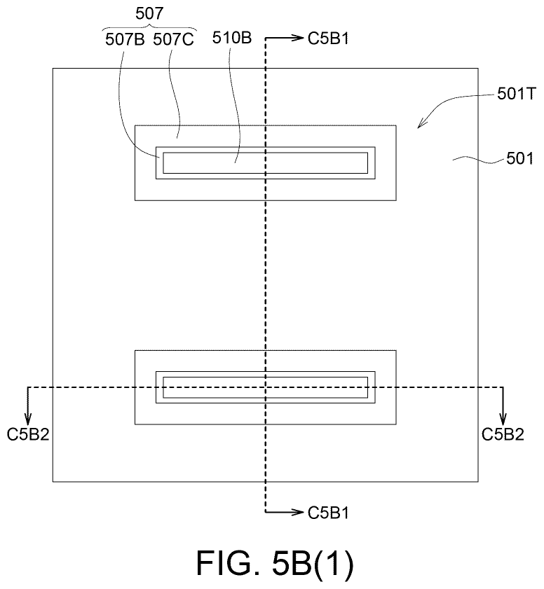

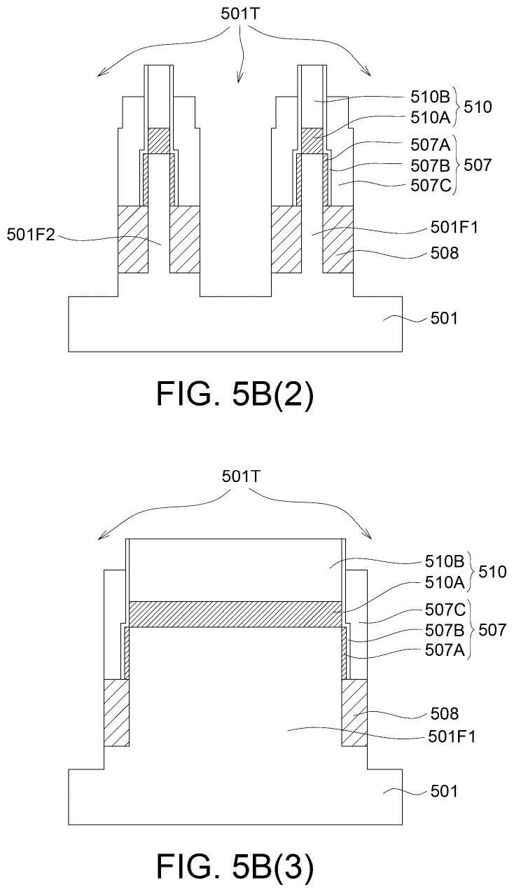

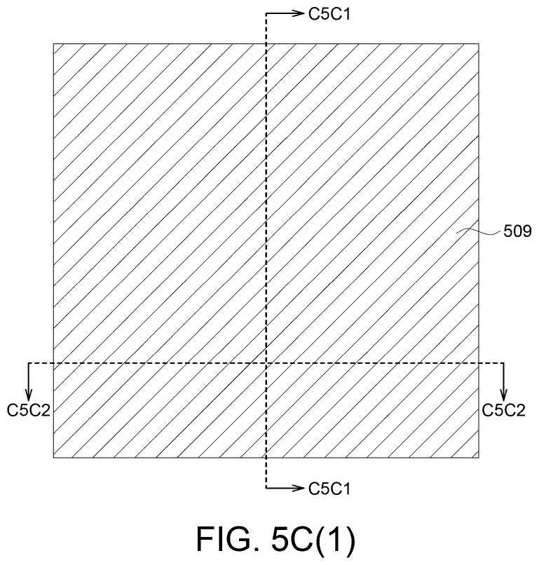

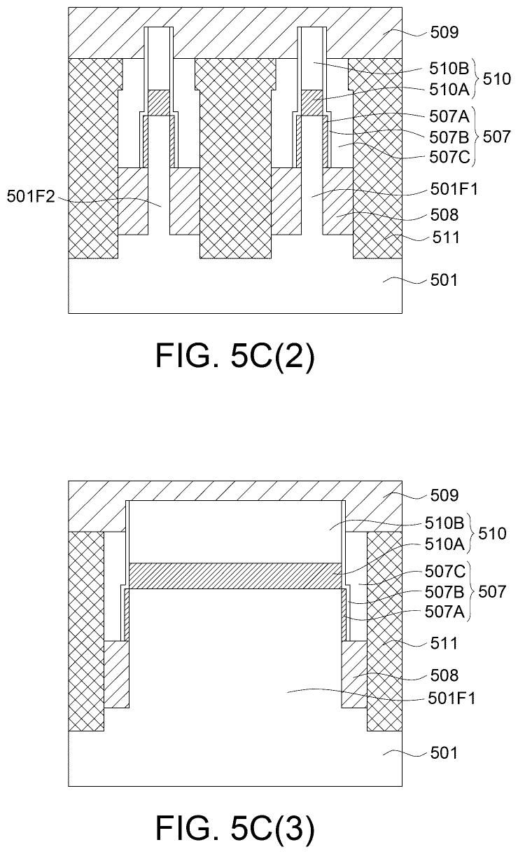

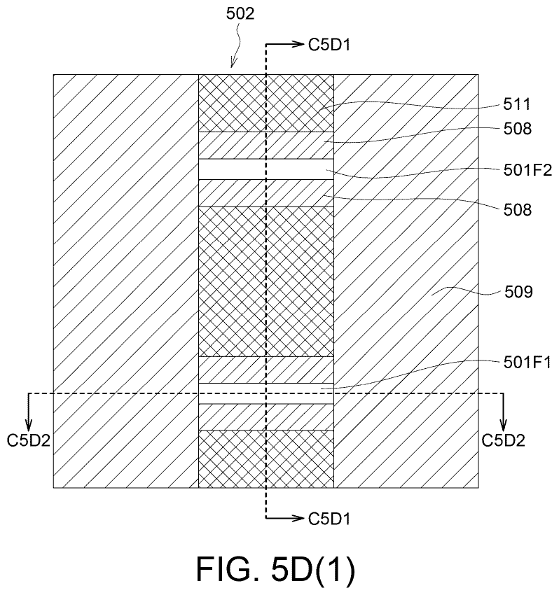

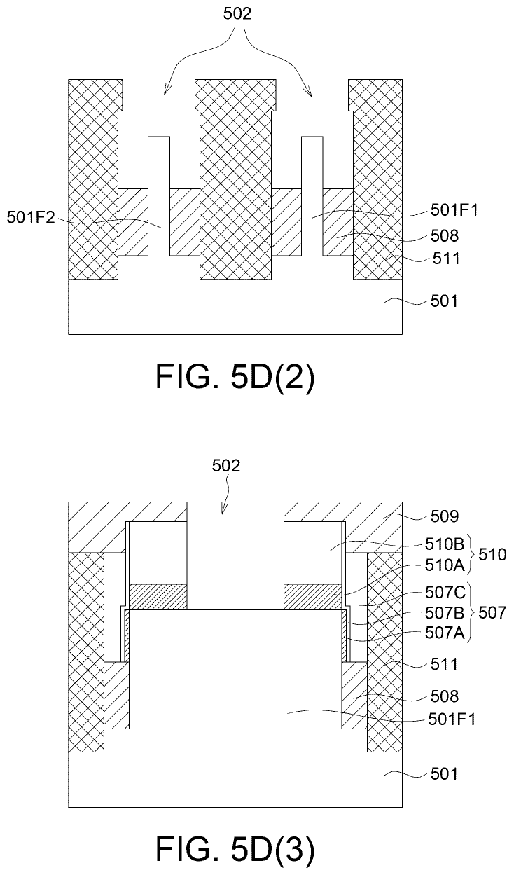

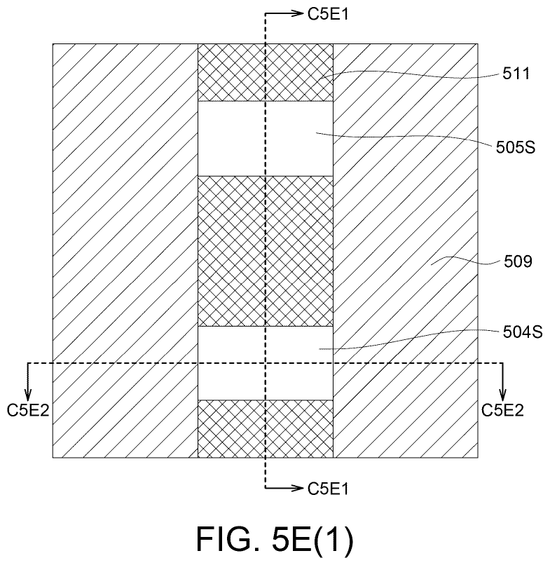

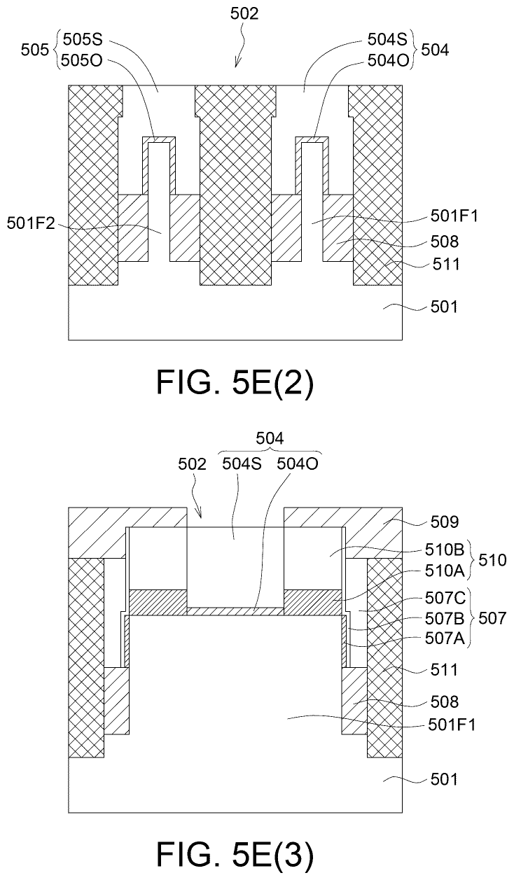

Referring to Step S51, a plurality of fin structures 501F1 and 501F2 are defined in a semiconductor substrate 501, each of the fin structures 501F1 and 501F2 is surrounded by a fin spacer 507. See FIGS. 5A(1) to 5A(3), FIG. 5A(1) is a top view illustrating the structure after the fin structures 501F1 and 501F2 are defined in the semiconductor substrate 501; FIG. 5A(2) is a cross-sectional view taken along the cutting line C5A1 as depicted in FIG. 5A(1); and FIG. 5A(3) is a cross-sectional view taken along the cutting line C5A2 as depicted in FIG. 5A(1). The fin structures 501F1 and 501F2 are defined by Sub-Steps S511-S515 as follows:

Referring to sub-step S511: An etching process, using a patterned pad dielectric layer 510 (including a patterned pad oxide layer 510A and a patterned pad nitride layer 510B) as an etching mask, is performed to remove parts of silicon material of a semiconductor substrate 501 to create trenches 501T and define a plurality of fin structures 501F1 and 501F2 in the semiconductor substrate 501. In some embodiments, the distance of the adjacent two fin structures 501F1 and 501F2 may be about 30-50 nm. Each of the fin structures 501F1 and 501F2 has a thickness about 3-10 nm, such as 5 nm.

Referring to sub-step S512: a shallow trench isolation (STIs) 508 is formed surrounding the fin structures 501F1 and 501F2. In some embodiments of the present disclosure, oxide material is deposited to fully fill the trenches 501T and then etched back, such that the oxide material remained in the trenches 501T can serve as the STIs 508 surrounding the plurality of fin structures 501F1 and 501F2. Referring to Sub-step S513: An etching back process is performed to remove portions of the shallow trench isolation (STI) regions 508, so as to expose sidewalls of the fin structures 501F1 and 501F2.

Next, referring to sub-step S514: A thermal oxidation process is performed to form the oxide spacers 307A on the sidewalls of the fin structures 501F1 and 501F2. Then referring to sub-step S515: A nitride deposition process is performed to form the nitride spacers 507B on the oxide spacers 507A. And referring to sub-step S516: Amorphous silicon spacers 507C (serving as a sacrificial spacer) are formed on the nitride spacers 507B. In some embodiments of the present disclosure, the forming of the amorphous silicon spacers 507C includes steps of depositing amorphous silicon to cover the fin spacer 507, the shallow trench isolation (STIs) 508 and the fin structures 501F1 and 501F2; and performing an anisotropic etching process to removing portions of the amorphous silicon and to remain the portion of the amorphous silicon disposed on the sidewalls of the nitride spacers 507B. Each of the amorphous silicon spacers 507C has a thickness about 5-10 nm.

Referring to step S52: The portion of the STI regions 508 not covered by the fin spacers 507 (including oxide spacers 507A, the nitride spacers 507B and the amorphous silicon spacers 507C) is removed to expose the portion of the semiconductor substrate 501 beneath the removed portion of the STI regions 508. See FIGS. 5B(1) to 5B(3), FIG. 5B(1) is a top view illustrating the structure after the portion of the STIs 508 not covered by the fin spacers 507 is removed; FIG. 5B(2) is a cross-sectional view taken along the cutting line C5B1 as depicted in FIG. 5B(1); and FIG. 5B(3) is a cross-sectional view taken along the cutting line C5B2 as depicted in FIG. 5B(1).

In the present embodiment, a portion of the semiconductor substrate 501 beneath the removed portion of the STIs 508 can be also removed, so as to make the top surface of the remaining portion of the semiconductor substrate 501 is lower than the bottom of the remained STI regions 508.

Referring to step S53: Gate opening 502 is defined in a capping dielectric layer 509 covering the fin structures 501F1 and 501F2 and the STIs 508, wherein the sidewalls of each of the fin structures 501F1 and 501F2 are partially exposed from corresponding one of the gate openings 502. wherein Step S53 includes Sub-steps S531-S534:

Referring to Sub-step S531: An inserting dielectric layer 511 is formed to surround the sidewalls of the fin structures 501F1 and 501F2, and referring to Sub-step S532: An oxide deposition process is performed to form the capping dielectric layer 509 on the fin structures 501F1 and 501F2 and the inserting dielectric layer 511. See FIGS. 5C(1) to FIG. 5C(3), FIG. 5C(1) is a top view illustrating the structure after the inserting dielectric layer 511 and the capping dielectric layer 509 are formed; FIG. 5C(2) is a cross-sectional view taken along the cutting line C5C1 as depicted in FIG. 5C(1); and FIG. 5C(3) is a cross-sectional view taken along the cutting line C5C2 as depicted in FIG. 5C(1).

In some embodiments of the present disclosure, the material constituting the dielectric layer 511 may be different from that constituting the capping dielectric layer 509. In the present embodiment, the dielectric layer 511 is formed by a low-k dielectric material (such as, SiCOH) deposition process to covering the top surface of the remaining portion of the semiconductor substrate 501. The deposited low-k dielectric material may be planarized by a chemical-mechanical polishing (CMP), and then etched backed using the patterned pad nitride layer 510B, nitride spacers 507B and the amorphous silicon spacers 507C as an etching stop layer. Such that, the patterned pad nitride layer 510B, nitride spacers 507B and the amorphous silicon spacers 507C can be exposed from the partially filled trenches 501T.

Sub-step S532: the oxide deposition process for forming the capping dielectric layer 509 includes depositing SiO₂ to fulfill the trenches 501T and is followed by a planarization process (such as, CMP). The bottom of the inserting dielectric layer 511 (SiCOH) is lower than the bottom of the remained STI regions 508. Since the dielectric constant of the inserting dielectric layer 511 (SiCOH) is lower than that of the STI regions 508, therefore, the coupling effect between two gate structures 504 and 506 (as shown below) could be improved.

Referring to Sub-step S533: A patterned process is performed to remove a portion of the capping dielectric layer 509 to define the gate opening 502. In some embodiment, a patterned photoresist layer (not shown) is formed on the capping dielectric layer 509 to expose the portion of the capping dielectric layer 509 covering the fin structures 501F1 and 501F2. Then, an etching process is performed to remove the exposed portion of the capping dielectric layer 509 to define the gate opening 502 in the capping dielectric layer 509.

Referring to Sub-step S534: the amorphous silicon spacers 507C, the nitride spacers 507B and the oxide spacers 507A are removed, so as to make each of the fin structures 501F1 and 501F2 partially exposed from the gate opening 502. In the present embodiment, after the gate opening 502 is defined in the capping dielectric layer 509, another etching process is performed to remove the amorphous silicon spacers 507C not covered by the patterned photoresist layer (not shown) from the gate opening 502.

Next, another process is performed remove the nitride spacers 507B and the portion of the patterned pad nitride 510B from the gate opening 502. After the patterned photoresist layer PR is peered, the oxide spacers 507A and the portion of the patterned pad oxide layer 510A exposed from the gate opening 502 are removed by another etching process, so as to expose the tops and sidewalls of each fin structures 501F1 and 501F2. See FIGS. 5D(1) to FIG. 5D(3), FIG. 5D(1) is a top view illustrating the structure after the fin structures 501F1 and 501F2 are partially exposed from the gate opening 502; FIG. 5D(2) is a cross-sectional view taken along the cutting line C5D1 as depicted in FIG. 5D(1); and FIG. 5D(3) is a cross-sectional view taken along the cutting line C5D2 as depicted in FIG. 5D(1).

Referring to Steps S54: Gate structures 504 and 505 are formed respectively on the fin structures 501F1 and 501F2. See FIGS. 5E(1) to 5E(3). FIG. 5E(1) is a top view illustrating the structure after the gate structures 504 and 505 are formed; FIG. 5E(2) is a cross-sectional view taken along the cutting line C5E1 as depicted in FIG. 5E(1); and FIG. 5E(3) is a cross-sectional view taken along the cutting line C5E2 as depicted in FIG. 5E(1).

The Step S54 for forming the gate structures 504 and 505 includes Sub-steps S541-S542: Referring to Sub-step S541: The gate dielectric layers 504O and 505O are formed respectively covering the tops and sidewalls of the fin structures 501F1 and 501F2. In some embodiments of the present disclosure, the gate dielectric layers 504O and 505O are formed by an oxide deposition process. Then, referring to Sub-step S542: The gate electrodes 504S and 505S are formed respectively covering the gate dielectric layers 504O and 505O. In some embodiments of the present disclosure, the gate electrodes 504S and 505S are formed by polysilicon or metal. After the forming of the gate structures 504 and 505, the capping dielectric layer 309 is then removed, and the source/drain regions could be formed as previously mentioned.

Compared with Embodiment II, in the present embodiment, between two gate structures 504 and 505, the bottom of the inserting dielectric layer 511 (SiCOH) is lower than the bottom of the STIs 508. Since the dielectric constant of the inserting dielectric layer 511 (SiCOH) is lower than that of the STI region 508, therefore, the coupling effect between two gate structures 504 and 505 could be improved.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for forming a metal-oxide-semiconductor (MOS) transistor structure, comprising:
defining a first fin structure and a second fin structure adjacent to the first fin structure in a semiconductor substrate, wherein a shallow trench isolation (STI) region is between the first fin structure and the second fin structure;
forming a first sacrificial spacer disposed along sidewalls of the first fin structure and forming a second sacrificial spacer disposed along sidewalls of the second fin structure, wherein a gap is between the first sacrificial spacer and the second sacrificial spacer;
forming an inserting dielectric layer to fill the gap between the first sacrificial spacer and the second sacrificial spacer;
removing the first sacrificial spacer and the second sacrificial spacer; and
forming two gate structures over the first fin structure and the second fin structure respectively, wherein the two gate structures are separated by the inserting dielectric layer.

2. The method according to claim 1, wherein the first sacrificial spacer and the second sacrificial spacer comprise an epitaxial semiconductor material selectively grown based on the sidewalls of the first fin structure and the second fin structure.

3. The method according to claim 2, prior to forming the first sacrificial spacer and the second sacrificial spacer, further comprising:
forming a capping dielectric layer covering the first fin structure and the second fin structure; and
defining a gate opening in the capping dielectric layer to make the sidewalls of the first fin structure and the second fin structure partially exposed from the gate opening.

4. The method according to claim 3, further comprising:
forming a fin spacer to surround the sidewalls of the first fin structure and the second fin structure, prior to forming the capping dielectric layer; and
performing at least one etching process to remove the fin spacer in the gate opening to make the sidewalls of the first fin structure and the second fin structure partially exposed, prior to forming the first sacrificial spacer and the second sacrificial spacer.

5. The method according to claim 3, wherein a material of the inserting dielectric layer is different from that of the capping dielectric layer.

6. The method according to claim 3, further comprising: deepening the gate opening to expose the semiconductor substrate, after the epitaxial semiconductor material is formed and prior to the gate opening is filled with the inserting dielectric layer.

7. The method according to claim 6, wherein a portion of the semiconductor substrate is removed during the process of deepening the gate opening.

8. The method according to claim 6, wherein a portion of the STI region is removed during deepening the gate opening, so as to remain another portion of the STI region beneath the epitaxial semiconductor material.

9. The method according to claim 8, wherein a bottom of the inserting dielectric layer is lower than a bottom of the another portion of the STI region.

10. The method according to claim 1, wherein a dielectric constant of the inserting dielectric layer is lower than that of SiO₂.

11. The method according to claim 1, wherein the first sacrificial spacer and the second sacrificial spacer comprises amorphous silicon covering the sidewalls of the first fin structure the second fin structure.

12. The method according to claim 11, further comprising:
forming a fin spacer to surround the sidewalls of the first fin structure and the second fin structure, prior to forming the first sacrificial spacer and the second sacrificial spacer.

13. The method according to claim 11, further comprising:
forming a capping dielectric layer covering the first fin structure, the second fin structure, the first sacrificial spacer, the second sacrificial spacer and the inserting dielectric layer; and
defining a gate opening in the capping dielectric layer to make the sidewalls of the first fin structure and the second fin structure partially exposed from the gate opening.

14. The method according to claim 11, further comprising:
removing a portion of the STI region not covered by the first sacrificial spacer and the second sacrificial spacer to expose a portion of the semiconductor substrate, prior to removing the sacrificial spacer.

15. The method according to claim 14, wherein a bottom of the inserting dielectric layer is lower than a bottom of another portion of the STI region beneath the first sacrificial spacer and the second sacrificial spacer.

16. A metal-oxide-semiconductor (MOS) transistor structure, comprising:
a first active region and a second active region adjacent to the first active region in a semiconductor substrate, wherein a shallow trench isolation (STI) region is between the first active region and the second active region;
an inserting dielectric layer disposed between the first active region and the second active region;
a first trench surrounding or over the first active region, wherein the first trench is adjacent to one side of the inserting dielectric layer;
a second trench surrounding or over the second active region, wherein the second trench is adjacent to another side of the inserting dielectric layer;
a first gate structure over the first active region and within the first trench, wherein the first gate structure covers a first portion of the STI region;
a second gate structure over the second active region and within the first trench, wherein the second gate structure covers a second portion of the STI region;
a first source region and a first drain region electrically contacting to a first channel within the first active region; and
a second source region and a second drain region electrically contacting to a second channel within the second active region;
wherein a distance between the first gate structure and the second gate structure is decided by the inserting dielectric layer.

17. The MOS transistor structure according to claim 16, wherein a width of the inserting dielectric layer between the active region and the second active region is not defined by a photolithographic process.

18. A metal-oxide-semiconductor (MOS) transistor structure, comprising:
a first fin structure and a second fin structure adjacent to the first fin structure in a semiconductor substrate, wherein a shallow trench isolation (STI) region is between the first fin structure and the second fin structure;
an inserting dielectric layer disposed between the first fin structure and the second fin structure;
a first trench surrounding or over the first fin structure, wherein the first trench is adjacent to one side of the inserting dielectric layer;
a second trench surrounding or over the second fin structure, wherein the second trench is adjacent to another side of the inserting dielectric layer;
a first gate structure over the first fin structure and within the first trench, wherein the first gate structure covers a first portion of the STI region; and
a second gate structure over the second fin structure and within the first trench, wherein the second gate structure covers a second portion of the STI region;
wherein a bottom of the inserting dielectric layer is lower than that of the first portion of the STI region or the second portion of the STI region.

19. The MOS transistor structure according to claim 16, further comprising:
a first source region and a first drain region electrically contacting to a first channel within the first fin structure; and
a second source region and a second drain region electrically contacting to a second channel within the second fin structure.
